(19) United States
(12) Patent Application Publication
(10) Pub. No.: US 2026/0059849 A1
(43) Pub. Date: Feb. 26, 2026

(54) SEMICONDUCTOR DEVICE AND METHOD OF MANUFACTURING THE SAME

(71) Applicant: SAMSUNG ELECTRONICS CO., LTD., SUWON-SI (KR)

(72) Inventors: SANGJINE PARK, SUWON-SI (KR); YOUNGJUN KIM, SUWON-SI (KR)

(21) Appl. No.: 19/070,882

(22) Filed: Mar. 5, 2025

(30) Foreign Application Priority Data
Aug. 22, 2024 (KR) 10-2024-0113005

(51) Int. Cl. H10D 84/83; H01L 23/522; H01L 23/528; H01L 23/532; H10D 30/00; H10D 30/01; H10D 30/43; H10D 62/10; H10D 62/13; H10D 64/23; H10D 84/01

(52) U.S. Cl. CPC H10D 84/832; H01L 23/5226; H01L 23/5283; H01L 23/53295; H10D 30/43; H10D 30/502; H10D 62/121; H10D 62/151; H10D 64/256; H10D 84/8312; H10D 30/014; H10D 30/019; H10D 84/0149

(57) ABSTRACT

A semiconductor device includes: a base pattern; a first metal structure penetrating the base pattern in a first direction; at least one gate structure including a gate electrode disposed on the first metal structure in the first direction; a second metal structure penetrating the base pattern in the first direction and spaced adjacent to the first metal structure in a second direction intersecting the first direction; and a source/drain structure including at least one of a source electrode or a drain electrode disposed on the second metal structure in the first direction, wherein the first metal structure and the second metal structure are electrically separated from each other by a blocking film.

### CROSS-REFERENCE

This application claims priority under 35 U.S.C. § 119 to Korean Patent Application No. 10-2024-0113005, filed on Aug. 22, 2024 in the Korean Intellectual Property Office, the disclosure of which is incorporated by reference herein in its entirety.

### FIELD

The present disclosure generally relates to semiconductor devices, and more particularly relates to a semiconductor device and a method of manufacturing the semiconductor device.

### INTRODUCTION

As one of various scaling technologies for enhancing the density of a semiconductor device, a multi-gate transistor may be applied in which a fin-shaped or nanowire-shaped multi-channel active pattern or silicon body may be formed on a substrate, and a gate may be formed on the surface of the multi-channel active pattern.

The term “front end of line” (FEOL) may be used with reference to the first portion of an integrated circuit (IC) fabrication where the individual devices are patterned in the semiconductor, and the term “back end of line” (BEOL) may be used with reference to the subsequent deposition of metal interconnect layers. A source/drain structure and a gate structure in various semiconductor devices, such as a logic circuit, may be connected to metal wiring, such as a BEOL, through contact structures.

When forming these contact structures, space constraints may apply to secure alignment between the contact structures, such as in highly integrated and miniaturized semiconductor devices. When enough space is not readily available in a horizontal direction, contact structures may be further disposed to be spaced apart in a vertical direction, which might increase the height of a semiconductor device. A misalignment between contact structures may lead to a defect such as a short-circuit, which might reduce the yield, performance, and/or reliability of the semiconductor device.

### SUMMARY

Embodiments of the present disclosure may include a semiconductor device in which reliability is optimized, and a method of manufacturing the same.

Embodiments are not limited to those described herein, and alternate embodiments may become apparent to those of ordinary skill in the art to which the present disclosure pertains based on the following description and the accompanying drawings.

According to an embodiment, there is provided a semiconductor device comprising: a base pattern; a first metal structure penetrating the base pattern in a first direction; at least one gate structure including a gate electrode disposed on the first metal structure in the first direction; a second metal structure penetrating the base pattern in the first direction and spaced adjacent to the first metal structure in a second direction intersecting the first direction; and a source/drain structure including at least one of a source electrode or a drain electrode disposed on the second metal structure in the first direction, wherein the first metal structure and the second metal structure are electrically separated from each other by a blocking film.

According to an embodiment, there is provided a semiconductor device including a rear side base pattern, an active pattern on the rear side base pattern, a gate structure including a gate electrode configured to surround the active pattern disposed in a first direction, a source/drain structure disposed on the rear side base pattern in the first direction and disposed to be connected to the active pattern in a second direction intersecting the first direction, a first metal structure formed to penetrate the rear side base pattern in the first direction and connected to the gate structure, and a second metal structure disposed to be spaced apart from the first metal structure in the second direction and connected to the source/drain structure in the first direction, and the first metal structure and the second metal structure may be electrically separated by a blocking film.

According to an embodiment, there is provided a semiconductor device including a rear side base pattern, an active pattern on the rear side base pattern, a gate structure including a gate electrode configured to surround the active pattern disposed in a first direction, a first source/drain structure and a second source/drain structure disposed on the rear side base pattern in the first direction, disposed to be connected to the active pattern in a second direction intersecting the first direction, and disposed to be spaced apart from each other with the gate structure in between in the second direction, a rear side gate contact formed to penetrate the rear side base pattern in the first direction and connected to the gate structure, a first source/drain contact connected to the first source/drain structure, and a second source/drain contact connected to the second source/drain structure, and the first source/drain contact, the rear side gate contact, and the second source/drain contact may be disposed to be spaced apart sequentially in the second direction, and a blocking film may be interposed between the rear side gate contact and the first source/drain contact and between the rear side gate contact and the second source/drain contact.

According to an embodiment, there is provided a semiconductor device including a rear side base pattern, an active pattern on the rear side base pattern, a gate structure including a gate electrode configured to surround the active pattern disposed in a first direction, a first source/drain structure and a second source/drain structure disposed on the rear side base pattern in the first direction, connected to each other through the active pattern, and disposed to be spaced apart from each other with the gate structure in between in a second direction intersecting the first direction, a first gate rear side structure, a second gate rear side structure, and a third gate rear side structure configured to penetrate the rear side base pattern in the first direction, formed to decrease in width from upper portions toward lower portions, and connected to the gate structure, a first source/drain contact connected to the first source/drain structure, a second source/drain contact connected to the second source/drain structure, a first blocking film formed at a lower portion of the rear side base pattern configured to surround side surfaces of the first gate rear side structure, the second gate rear side structure, and the third gate rear side structure, and a second blocking film configured to surround each of a side surface of the first source/drain contact and a side surface of the second source/drain contact, and the first blocking film may be in contact with at least a portion of each of the side surfaces of the first gate rear side structure, the second gate rear side structure, and the third gate rear side structure and at least a portion of a side surface of the second blocking film, and some of the first gate rear side structure, the second gate rear side structure, and the third gate rear side structure may be in contact with an interlayer insulating film in the first direction and others may be in contact with a rear side via connected to a wiring line.

Additional embodiments may be set forth at least in part in the description which follows and/or may become apparent at least in part from this description.

According to an embodiment of the present disclosure, a semiconductor device may be miniaturized and the reliability thereof may be optimized.

In addition, according to an embodiment of the present disclosure, a contact structure may be disposed at an accurate position.

In addition, according to an embodiment of the present disclosure, conduction between neighboring contact structures may be prevented.

Embodiments are not limited to those described above, and other embodiments may be clearly understood by those of ordinary skill in the art to which the present disclosure pertains as bounded by the appended claims.

### BRIEF DESCRIPTION OF THE DRAWINGS

These and/or other embodiments of the present disclosure will become apparent and more readily appreciated based on the following description when taken in conjunction with the accompanying drawings, in which:

FIG. 1 is a layout diagram with cutting plane placements illustrating a semiconductor device according to an illustrative embodiment;

FIG. 2 is a sectional diagram schematically showing a cross-section taken normal to a cutting plane A-A of FIG. 1;

FIG. 3 is a sectional diagram schematically showing a cross-section taken normal to a cutting plane B-B of FIG. 1;

FIG. 4 is a sectional diagram schematically showing a cross-section taken normal to a cutting plane C-C of FIG. 1;

FIGS. 5A-C are sectional diagrams illustrating an intermediate stage in a method of manufacturing the semiconductor device of FIG. 1;

FIGS. 6A-C are sectional diagrams illustrating an intermediate stage in a method of manufacturing the semiconductor device of FIG. 1;

FIGS. 7A-C are sectional diagrams illustrating an intermediate stage in a method of manufacturing the semiconductor device of FIG. 1;

FIGS. 8A-C are sectional diagrams illustrating an intermediate stage in a method of manufacturing the semiconductor device of FIG. 1;

FIGS. 9A-C are sectional diagrams illustrating an intermediate stage in a method of manufacturing the semiconductor device of FIG. 1;

FIGS. 10A-C are sectional diagrams illustrating an intermediate stage in a method of manufacturing the semiconductor device of FIG. 1;

FIGS. 11A-C are sectional diagrams illustrating an intermediate stage in a method of manufacturing the semiconductor device of FIG. 1;

FIGS. 12A-C are sectional diagrams illustrating an intermediate stage in a method of manufacturing the semiconductor device of FIG. 1; and

FIGS. 13A-C are sectional diagrams illustrating an intermediate stage in a method of manufacturing the semiconductor device of FIG. 1.

### DETAILED DESCRIPTION

Illustrative embodiments of the present disclosure are described below and may be modified and/or implemented in various forms, but the present disclosure is not limited to the embodiments described herein. Terms used in this description may be selected from currently used general terms when possible, while considering the functions in the present disclosure, excluding terms arbitrarily selected herein by the applicant if the intended meaning thereof is described or otherwise clear to one skilled in the pertinent art. However, terms may vary depending on the intention of a person skilled in the art, precedents, the emergence of new technology, and the like. In addition, the words and terminologies used in the specification and claims are not to be construed as limited to common or dictionary meanings but construed as including meanings and conceptions coinciding with the technical spirit of the present disclosure.

In the present disclosure, when a part is described as “comprising or including” a component, it does not exclude another component but may further include another component unless otherwise stated. For example, it should be understood that terms such as “comprise”, “include” and “have” are intended to indicate the presence of a feature, a number, a step, an operation, an element, a component, or a combination thereof which are described in the specification, and not intended to exclude the possibility of the presence or addition of one or more other features, numbers, steps, operations, elements, components, or combinations thereof.

In the present disclosure, a singular expression includes a plural expression unless otherwise apparent and/or defined by context. In addition, although the terms “first”, “second”, or the like may be used to describe various elements, such elements should not be limited by these terms, and the above terms may be used to distinguish one element from another. For example, a first element may be referred to as a second element, and similarly, a second element may be referred to as a first element within the scope of the present disclosure. Further, the shape and/or size of elements in drawings may be exaggerated for clearer description. In addition, expressions such as “upper side,” “lower side,” “above,” “below,” “upper portion,” “lower portion,” “side surface,” “upper surface,” and “lower surface” hereinafter are represented based on a direction illustrated in a given drawing and may be represented otherwise when the direction of a corresponding object changes.

To facilitate efficient understanding, existing components, structures, or films of semiconductor devices and materials forming these may be described in greater detail within the specification, but need not be further described if substantially similar to those already described herein or otherwise apparent to those skilled in the pertinent field of art. For example, a predetermined insulating film and structure included in a semiconductor device, and materials forming these, may be omitted when not closely related to features of an embodiment described below.

In addition, the drawings depicting the semiconductor device described below may illustrate a fin field-effect transistor (FinFET) including a channel region in a fin-type pattern, a transistor including nanowire or nanosheet, and/or a multi-bridge channel field effect transistor (MBCFET) for example, but embodiments of the present disclosure are not limited thereto.

Further, a semiconductor device may include a tunneling FET, a three-dimensional (3D) transistor, or a vertical FET. Moreover, the semiconductor device is may also include a planar transistor, without limitation thereto. In addition, the present disclosure may be similarly applied to two-dimensional (2D) material-based FETs and a heterostructure thereof. Moreover, the semiconductor device according to an embodiment may also include a bipolar junction transistor and a lateral double-diffused metal-oxide-semiconductor (LDMOS) transistor.

Hereinafter, an embodiment of the present disclosure will be described in detail with reference to the accompanying drawings so that those of ordinary skill in the pertinent field of art to which the present disclosure pertains may easily implement embodiments of the present disclosure.

In an embodiment of the present disclosure, a blocking film may be interposed between first metal structures, at least some of which may each function as a gate contact, and second metal structures, some of which may each function as a source contact and others of which may each function as a drain contact, to minimize or prevent misalignment, short-circuits and/or conduction between each first metal structure and each second metal structure. The first metal structures may have substantially tapered shapes and may function as gate contacts and/or as alignment structures. For example, some of the first metal structures may each function as a gate contact and others may each function as an alignment structure, and/or some may function as both.

The blocking film may include a first blocking film and a second blocking film. The first blocking film may extend in a substantially horizontal direction surrounding base portions of the first metal structures, and the second blocking film may extend in a substantially vertical direction surrounding side portions of the second metal structures. For example, the first blocking film may be or include an oxide film surrounding a lower side surface of a first metal structure, and may be formed as a substrate is oxidized in a polishing process. For example, the second blocking film may be or include a liner surrounding a side surface of a second metal structure. Moreover, the second blocking film and the second metal structure may have a structure that is indented above a lower surface of a gate structure.

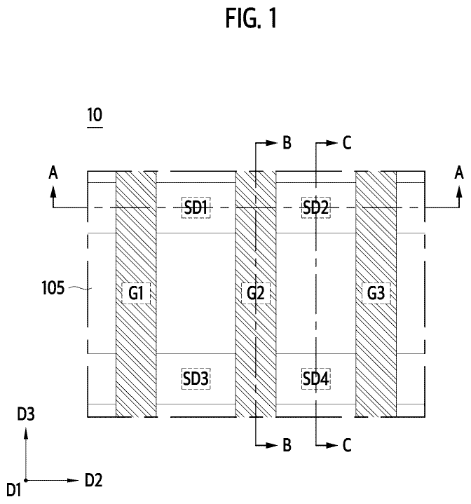

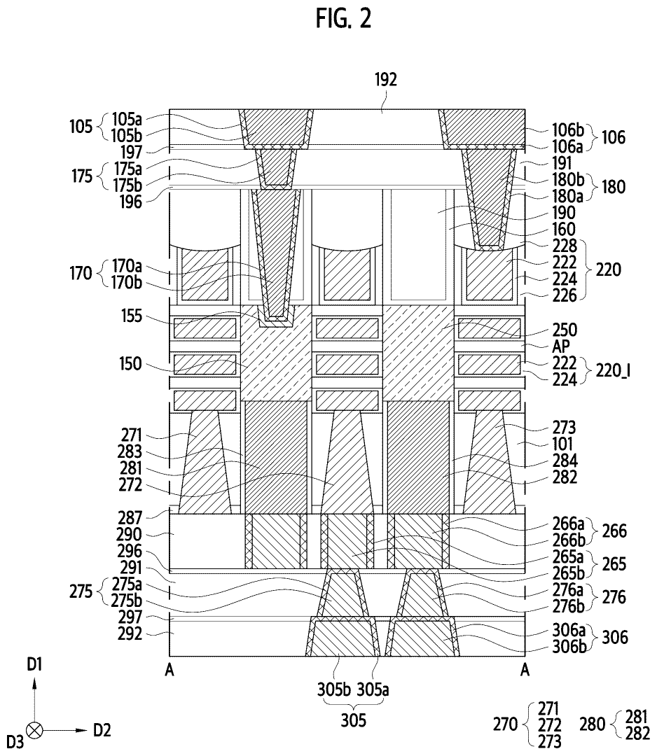

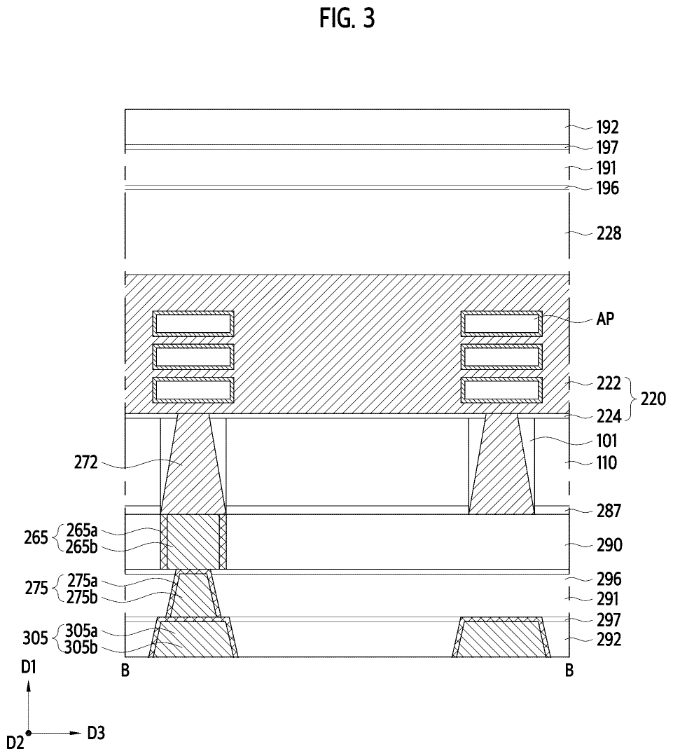

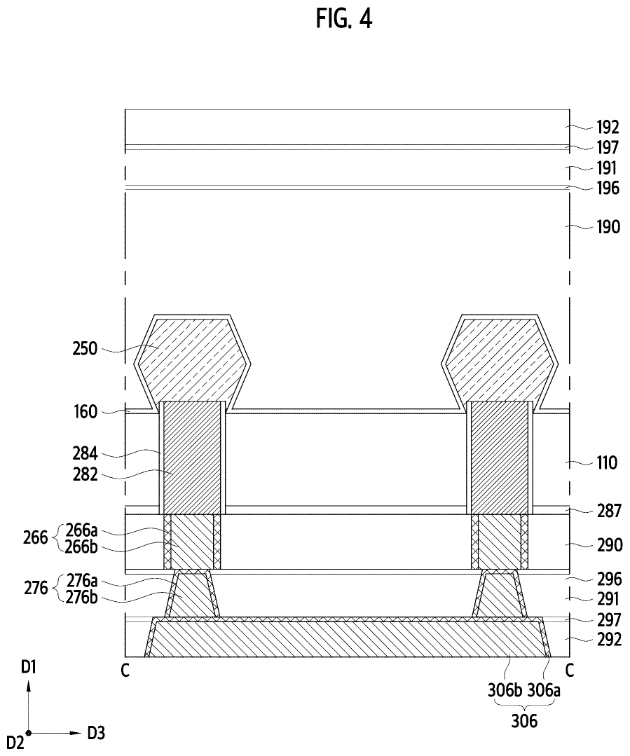

FIG. 1 shows a semiconductor device according to an embodiment. FIG. 2 shows a cross-section viewed normal to a cutting plane A-A of FIG. 1. FIG. 3 shows a cross-section viewed normal to a cutting plane B-B of FIG. 1. FIG. 4 shows a cross-section viewed normal to a cutting plane C-C of FIG. 1.

Referring to FIGS. 1 to 4, a semiconductor device 10, according to an embodiment of the present disclosure, may include a rear side base pattern 101, a first front side wiring line 105, a first source/drain structure 150, a gate structure 220, a second source/drain structure 250, a first metal structure 270, and a second metal structure 280.

According to an embodiment, the gate structure 220, the first source/drain structure 150, and the second source/drain structure 250 may be disposed on the rear side base pattern 101. Hereinafter, to facilitate efficient understanding, a direction in which the rear side base pattern 101 and the gate structure 220 are disposed is defined as a first direction D1, and a direction intersecting the first direction D1 when the semiconductor device 10 is viewed laterally is defined as a second direction D2. For example, the second direction D2 may be substantially perpendicular to the first direction D1, without limitation thereto.

In addition, a direction intersecting a plane including both the first direction D1 and the second direction D2 is defined as a third direction D3. For example, the third direction D3 may be substantially perpendicular to the plane, without limitation thereto.

According to an embodiment, the first direction D1 may be a direction perpendicular to the ground. Further, when a member is described, it may be understood that “front side” hereinafter may generally correspond to an upper surface of the corresponding member in the first direction D1, and “rear side” may generally correspond to a lower surface thereof.

According to an embodiment, the semiconductor device 10 may include source/drain regions SD1 to SD4 and gate regions G1 to G3. The source/drain structures 150 and 250 may be positioned in the source/drain regions SD1 to SD4, such as source/drain structure 150 in source/drain region SD1 and source/drain structure 250 in source/drain region SD2 without limitation thereto, and the gate structure 220 or structures may be positioned in the gate regions G1 to G3. The source/drain regions SD1 to SD4 according to an embodiment may be arranged in the second direction D2 and the third direction D3, and the gate regions G1 to G3 may be arranged in the second direction D2 and extend in the first direction D1. According to an embodiment, the source/drain regions may include the first to fourth source/drain regions SD1 to SD4, without limitation, and the gate regions may include the first to third gate regions G1 to G3, without limitation. For example, the first gate region G1, the first source/drain region SD1, the second gate region G2, the second source/drain region SD2, and the third gate region G3 may be arranged sequentially in the second direction D2. In addition, the first gate region G1, the third source/drain region SD3, the second gate region G2, the fourth source/drain region SD4, and the third gate region G3 may also be arranged sequentially in the second direction D2, but offset in at least one other direction such as the third direction D3. from the first arrangement. Further, the first source/drain region SD1 may be arranged in the third direction D3 with the third source/drain region SD3. However, this is presented as an example to facilitate efficient understanding, and the number and arrangement of each region may be variously changed.

In addition, according to an embodiment, a shallow trench isolation (STI) structure may be disposed in a region such as, for example, a field region, between the first source/drain region SD1 and the third source/drain region SD3 and between the second source/drain region SD2 and the fourth source/drain region SD4. Moreover, the above-described two regions may be separated by a deep trench instead of the STI structure, without limitation thereto. An element isolation film 110, such as illustrated in FIG. 4, may be disposed in the field region. The first gate region G1, the first source/drain region SD1, the second gate region G2, the second source/drain region SD2, and the third gate region G3 of FIG. 1 may form any one active region; and the first gate region G1, the third source/drain region SD3, the second gate region G2, the fourth source/drain region SD4, and the third gate region G3 of FIG. 1 may form another active region. For example, a portion in which a channel region of a transistor is formed may be the active region, and a portion for dividing the channel region may be the field region, such as in an example of the semiconductor device 10. For example, the active region may be the channel region of the transistor. In addition, the active region may include an active pattern AP, as may be described in greater detail below. Further, the active region may be a portion where a fin-type pattern or a nanosheet is formed, and the field region may be a portion where no fin-type pattern or nanosheet is formed.

According to an embodiment, any one of the active regions may be an N-channel metal-oxide-semiconductor (NMOS)-formed region, and another may be a P-channel metal-oxide-semiconductor (PMOS)-formed region. According to some other an embodiment, all the active regions may be the PMOS-formed region. According to still other an embodiment, all the active regions may be the NMOS-formed region. Hereinafter, to facilitate efficient understanding, as an example of the active region, which is a region used as the channel region, a region including the first gate region G1, the first source/drain region SD1, the second gate region G2, the second source/drain region SD2, and the third gate region G3 is mainly described.

According to an embodiment, the rear side base pattern 101 may be disposed on a first rear side interlayer insulating film 290. In addition, the rear side base pattern 101 may be disposed in the first direction D1 with a plurality of active patterns AP. For example, the rear side base pattern 101 may be disposed below the active pattern AP in the first direction D1. For example, the rear side base pattern 101 may be disposed between a first rear side interlayer insulating film 290 and the active pattern AP. According to an embodiment, the rear side base pattern 101 may include an insulating material such as silicon (Si). For example, the rear side base pattern 101 may include at least one of silicon oxide, silicon nitride, silicon oxynitride, silicon-germanium (SiGe), a group IV semiconductor, a group III-V compound semiconductor, and/or a group II-VI compound semiconductor.

In an embodiment, as described above, the active pattern AP may be disposed above the rear side base pattern 101 in the first direction D1. In addition, the active pattern AP may be spaced apart from the rear side base pattern 101 in the first direction D1. The active pattern AP may be a multi-channel active pattern. For example, the active pattern AP may be disposed to be plural in number on the rear side base pattern 101. Any one active pattern AP may include a plurality of sheet patterns. For example, as illustrated in FIG. 2, each active pattern AP may include three sheet patterns, and each sheet pattern may be disposed to be spaced apart in the first direction D1. In addition, each sheet pattern may extend lengthwise in the second direction D2, and the plurality of active patterns AP may be disposed to be spaced apart in the third direction D3 on the rear side base pattern 101. According to an embodiment, the active pattern AP may be a pattern including a nanosheet or a nanowire.

In the above, it is described as an example that the active pattern AP includes three sheet patterns, but the present disclosure is not limited to this example. For example, the active pattern AP may have N sheet patterns, where N is a natural number greater than or equal to 1. In addition, FIG. 4 and the like illustrates that the sheet patterns of the active pattern AP may have a uniform width in the third direction D3, but the sheet patterns of the active pattern AP may have a shape with widths varied in the third direction D3. For example, the shape and arrangement of each sheet pattern may also be variously modified depending on design requirements.

In addition, according to an embodiment, the active pattern AP may include silicon, silicon-germanium (SiGe), group III-V compound semiconductor, group IV-IV compound semiconductor, germanium (Ge), graphene, oxide semiconductor, carbon nanotubes, or the like. In an embodiment, group III-V compound semiconductor may, for example, be a binary compound including at least one group III elements among boron (B), aluminum (Al), gallium (Ga), and indium (In) and at least one group V elements among nitrogen (N), phosphorus (P), arsenic (As), and antimony (Sb), a ternary compound, a quaternary compound, or a compound doped with other group III or group V elements thereto. Further, group IV-IV compound semiconductor may be a binary compound including at least two or more of carbon (C), silicon (Si), germanium (Ge), and tin (Sn), a ternary compound, or a compound doped with a group IV element thereto.

The element isolation film 110 according to an embodiment may be disposed in the field region described above. The element isolation film 110 may be disposed on the rear side base pattern 101. For example, the element isolation film 110 may partially overlap the active pattern AP in the first direction D1. In addition, the element isolation film 110 may be disposed between the active patterns AP disposed to be spaced apart in the third direction D3. Further, in an embodiment, the element isolation film 110 may cover a side surface of the rear side base pattern 101. In addition, an upper surface of the element isolation film 110 may be disposed to be flush with an upper surface of the rear side base pattern 101. Moreover, the element isolation film 110 may cover a portion alone of the side surface of the rear side base pattern 101, without limitation thereto. In this case, a portion of the rear side base pattern 101 may protrude more than the element isolation film 110 in the first direction D1. In an embodiment, the element isolation film 110 may include an oxide film, a nitride film, an oxynitride film, or a combination film thereof. In addition, the element isolation film 110 may be, but is not limited to, a film with a single layer.

According to an embodiment, the gate structure 220 may be disposed with the rear side base pattern 101 in the first direction D1. For example, the gate structure 220 may be disposed on the upper surface of the rear side base pattern 101 in the first direction D1. According to an embodiment, the gate structure 220 may be disposed to be plural in number on the rear side base pattern 101. The plurality of gate structures 220 may extend in the third direction D3. In addition, each gate structure 220 may be disposed to be spaced apart in the second direction D2.

In an embodiment, the gate structure 220 may be disposed to intersect the active pattern AP. For example, the gate structure 220 may be disposed to surround the active patterns AP. For example, the gate structure 220 may surround each of the sheet patterns of the active pattern AP.

According to an embodiment, the gate structure 220 may include a gate electrode 222, a gate insulating film 224, a gate spacer 226, and a gate capping film 228. The gate structure 220 according to an embodiment may include an inner gate structure 220_I. The inner gate structure 220_I may surround the active pattern AP. For example, the inner gate structure 220_I may be disposed between each of the plurality of sheet patterns disposed to be spaced apart in the first direction D1. In addition or alternately, the inner gate structure 220_I may be disposed between the upper surface of the rear side base pattern 101 and a sheet pattern closest to the rear side base pattern 101 among the plurality of sheet patterns disposed to be spaced apart in the first direction D1.

According to an embodiment, the number of the inner gate structures 220_I may correspond to the number of the sheet patterns of the active patterns AP, without limitation thereto. In addition, some of the inner gate structures 220_I may be in contact with the upper surface of the rear side base pattern 101 and a lower surface of a sheet pattern of the active pattern AP, and others of the inner gate structures 220_I may be in contact with each of an upper surface and the lower surface of the sheet pattern. Further, the inner gate structure 220_I may be in contact with the first source/drain structure 150 and/or the second source/drain structure 250, as may be described in greater detail below. Further, in an embodiment, the inner gate structure 220_I positioned at a lowermost portion in the first direction D1 among the inner gate structures 220_I may be in contact with an upper surface of the first metal structure 270, as may be described in greater detail below.

In an embodiment, the inner gate structure 220_I may include the gate electrode 222 and the gate insulating film 224 disposed each between sheet patterns of the active patterns AP adjacent in the first direction D1 and between the rear side base pattern 101 and the sheet patterns, but need not include a gate spacer 226 nor a gate capping film 228. The gate electrode 222 according to an embodiment may extend in the third direction D3. For example, the gate electrode 222 may extend in the third direction D3 between the first source/drain structures 150 and between the second source/drain structures 250. In addition, each gate electrode 222 may be spaced apart in the first direction D1 and the second direction D2. However, unlike the above examples, in some other an embodiment, the inner gate structure 220_I need not be formed.

In an embodiment, the gate electrode 222 may be in contact with the first metal structure 270. Accordingly, the gate electrode 222 and the first metal structure 270 may be electrically connected. This is described below in detail. In an embodiment, at least some of the gate electrodes 222 may be disposed at a position overlapping a front side gate contact 180, as may be described in greater detail below, in the first direction D1. Accordingly, at least some of the gate electrodes 222 may be connected to the front side gate contact 180. In addition, according to an embodiment, the gate electrode 222 may intersect the rear side base pattern 101 and the element isolation film 110. Further, the gate electrode 222 may surround the active patterns AP. In an embodiment, the gate electrode 222 may be disposed on the upper surface of the rear side base pattern 101 in the active region described above. In an embodiment, the gate electrode 222 need not overlap the element isolation film 110 in the second direction D2 or the third direction D3 in the active region. According to an embodiment, the gate electrode 222 may include at least one material among metal, metal alloy, conductive metal nitride, metal silicide, doped semiconductor material, conductive metal oxide, and conductive metal oxynitride. For example, the gate electrode 222 may include, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof. The conductive metal oxide and the conductive metal oxynitride may include, but are not limited to, an oxidized form of the materials described above. In addition, according to an embodiment, the gate electrode 222 may be formed of a single-layer or a multi-layered structure consisting of different materials.

The gate insulating film 224 according to an embodiment may surround the gate electrode 222. Accordingly, the gate insulating film 224 may be disposed between the gate electrode 222 and the sheet pattern of the active pattern AP. The gate insulating film 224 may extend along the upper surface of the rear side base pattern 101 and the upper surface of the element isolation film 110. Further, the gate insulating film 224 may surround the active patterns AP. For example, the gate insulating film 224 may be disposed along a perimeter of the sheet patterns of the active pattern AP. In an embodiment, the gate insulating film 224 may be in direct contact with the upper surface of the rear side base pattern 101. In addition, the gate insulating film 224 may be in direct contact with the upper surface of the element isolation film 110. In an embodiment, the gate insulating film 224 included in the inner gate structure 220_I described above may be in contact with the first source/drain structure 150 and the second source/drain structure 250, as may be described in greater detail below.

According to an embodiment, the gate insulating film 224 may include silicon oxide, silicon oxynitride, silicon nitride, or a high-permittivity material of which a dielectric constant is greater than that of silicon oxide. The high-permittivity material may include, for example, at least one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

In an embodiment, the gate insulating film 224 may be a single film or a plurality of films. For example, the gate insulating film 224 may include an interfacial layer disposed between the active pattern AP and the gate electrode 222 and a high-permittivity insulating film. In addition, the interfacial layer need not be formed along a profile of the upper surface of the element isolation film 110. Further, in some other an embodiment, the semiconductor device 10 may include a negative capacitor (NC) FET using an NC. In this case, for example, the gate insulating film 224 may include a ferroelectric material film having ferroelectric properties and a paraelectric material film having paraelectric properties. In an embodiment, the ferroelectric material film may have negative capacitance, and the paraelectric material film may have positive capacitance. For example, when two or more capacitors are connected serially and capacitance of each capacitor has a positive value, the total capacitance becomes less than the capacitance of each individual capacitor. In contrast, when at least one of capacitances of two or more capacitors serially connected has a negative value, the total capacitance may have a positive value, such as a value greater than an absolute value of each individual capacitance. When the ferroelectric material film with negative capacitance and the paraelectric material film with positive capacitance are connected serially, the total capacitance value of the ferroelectric material film and the paraelectric material film serially connected may increase. For example, using the increasing total capacitance value, a transistor including the ferroelectric material film may have a subthreshold swing (SS) of less than 60 millivolts/decade (mV/decade) at room temperature.

In an embodiment, the ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, hafnium zirconium oxide may be a material doped with zirconium (Zr) to hafnium oxide. As another example, hafnium zirconium oxide may be also a compound of hafnium (Hf), zirconium (Zr), and oxygen (O). In an embodiment, the ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material film includes, the type of dopant included in the ferroelectric material film may vary. In an embodiment, when the ferroelectric material film includes hafnium oxide, a dopant included in the ferroelectric material film may include, for example, at least one of gadolinium (Gd), silicon (Si), zirconium (Zr), aluminum (Al), and yttrium (Y). In an embodiment, when the dopant is aluminum (Al), the ferroelectric material film may include 3 to 8 atomic percent (at %) of aluminum. Here, a ratio of the dopant may be a ratio of aluminum to the sum of hafnium and aluminum. In an embodiment, when the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may include 1 to 7 at % of gadolinium. When the dopant is zirconium (Zr), the ferroelectric material film may include 50 to 80 at % of zirconium. In an embodiment, the paraelectric material film may have paraelectric properties. The paraelectric material film may include, for example, at least one of silicon oxide and metal oxide with high permittivity. For example, the metal oxide included in the paraelectric material film may include, but is not limited to, at least one of hafnium oxide, zirconium oxide, and aluminum oxide.

In an embodiment, the ferroelectric material film and the paraelectric material film may include a substantially the same material. While the ferroelectric material film may have ferroelectric properties, the paraelectric material film need not have ferroelectric properties. For example, when the ferroelectric material film and the paraelectric material film include hafnium oxide, a crystal structure of hafnium oxide included in the ferroelectric material film may be different from a crystal structure of hafnium oxide included in the paraelectric material film. In an embodiment, the ferroelectric material film may have a thickness with ferroelectric properties. For example, the thickness of the ferroelectric material film may be, but is not limited to, about 0.5 to about 10 nanometers (nm). Since a threshold thickness representing a ferroelectric property may vary for each ferroelectric material, the thickness of the ferroelectric material film may vary depending on ferroelectric materials. In an embodiment, the gate insulating film 224 may include one ferroelectric material film. In some other an embodiment, the gate insulating film 224 may include a plurality of ferroelectric material films spaced apart from each other. The gate insulating film 224 may have a stacked film structure in which a plurality of ferroelectric material films and a plurality of paraelectric material films are stacked alternately.

In an embodiment, the gate spacer 226 may be disposed on a side surface of the gate electrode 222. The gate spacer 226 need not be disposed between the rear side base pattern 101 and the active pattern AP in the first direction D1. In addition, the gate spacer 226 need not be disposed between the sheet patterns of the active pattern AP arranged in the first direction D1. According to an embodiment, the gate spacer 226 may include an insulating material. For example, the gate spacer 226 may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and/or a combination thereof. According to an embodiment, the gate spacer 226 may be a single film. Moreover, the gate spacer 226 may consist of a multilayer film, without limitation thereto.

The gate capping film 228 according to an embodiment may be disposed on the gate electrode 222. Further, in an embodiment, an upper surface of the gate capping film 228 may indicate an upper surface of the gate structure 220. In addition, unlike the drawings, in some other an embodiment, the gate capping film 228 may also be disposed between the gate spacers 226. The gate capping film 228 according to an embodiment may include an insulating material. For example, the gate capping film 228 may include at least one of silicon nitride (SiN), silicon oxynitride (SiON), silicon carbonitride (SiCN), silicon oxycarbonitride (SiOCN), and/or a combination thereof.

The first source/drain structure 150 and the second source/drain structure 250 according to an embodiment may be disposed in the active region described above. In addition, the first source/drain structure 150 and the second source/drain structure 250 may be disposed on the rear side base pattern 101. For example, the first source/drain structure 150 and the second source/drain structure 250 may be disposed between the gate electrodes 222 positioned adjacently in the second direction D2. For example, the first source/drain structure 150, the second source/drain structure 250, and the gate electrode 222 may be disposed in the second direction D2. In addition, each of the first source/drain structure 150 and the second source/drain structure 250 may be in contact with the active pattern AP.

In an embodiment, the first source/drain structure 150 may be positioned to overlap a first rear side source/drain contact 281, as may be described in greater detail below, in the first direction D1. In addition, the second source/drain structure 250 may be positioned to overlap a second rear side source/drain contact 282, as may be described in greater detail below, in the first direction D1. In an embodiment, upper surfaces of the source/drain structures 150 and 250 may be positioned to be flush with, or on substantially the same level as, a lower surface of a first front side etch stop film 196. In addition, lower surfaces of the source/drain structures 150 and 250 may be disposed above a lowermost surface of the gate structure 220. For example, vertical levels from a lower surface of the rear side base pattern 101 to the lower surfaces of the source/drain structures 150 and 250 in the first direction D1 may be greater than a vertical level from the lower surface of the rear side base pattern 101 to the lowermost surface of the gate structure 220 in the first direction D1.

In an embodiment, each of the first source/drain structure 150 and the second source/drain structure 250 may include an epitaxial pattern, without limitation to such crystalline layers or their orientations. Further, in an embodiment, each of the first source/drain structure 150 and the second source/drain structure 250 may include a semiconductor material. According to an embodiment, the first source/drain structure 150 and the second source/drain structure 250 may have different conductive types. For example, the first source/drain structure 150 may have n-type conductivity, and the second source/drain structure 250 may have p-type conductivity. In this case, the first source/drain structure 150 may include an n-type dopant, and the n-type dopant may include, but is not limited to, at least one of phosphorus (P), arsenic (As), antimony (Sb), and bismuth (Bi). In addition, the second source/drain structure 250 may include a p-type dopant. The p-type dopant may include, but is not limited to, at least one of boron (B) and gallium (Ga). However, the above examples are merely to facilitate efficient understanding, and the first source/drain structure 150 may also have p-type conductivity, and the second source/drain structure 250 may also have n-type conductivity.

According to an embodiment, a source/drain etch stop film 160 may extend along an outer side surface of the gate spacer 226, a side or upper surface of the first source/drain structure 150, and a side or upper surface of the second source/drain structure 250. The source/drain etch stop film 160 may extend along, such as substantially parallel to, the upper surface of the element isolation film 110. In addition, the source/drain etch stop film 160 may extend along a side surface of the gate capping film 228, but the present disclosure is not limited to these examples. For example, the source/drain etch stop film 160 may but need not also extend along the side surface of the gate capping film 228.

In an embodiment, the source/drain etch stop film 160 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and/or a combination thereof.

A first front side interlayer insulating film 190 according to an embodiment may be disposed on the source/drain etch stop film 160. In addition, the first front side interlayer insulating film 190 may be formed on the element isolation film 110 in the first direction D1. The first front side interlayer insulating film 190 may be disposed on the first source/drain structure 150 and the second source/drain structure 250 in the first direction D1. In addition, according to an embodiment, the first front side interlayer insulating film 190 need not cover the upper surface of the gate structure 220. For example, an upper surface of the first front side interlayer insulating film 190 may be placed to be flush with the upper surface of the gate structure 220.

In an embodiment, the first front side interlayer insulating film 190 may include an insulating material. For example, the first front side interlayer insulating film 190 may include at least one of silicon oxide, silicon nitride, silicon oxynitride, and/or a low-permittivity material. For example, the low-permittivity material may include, but is not limited to, fluorinated tetra ethyl ortho silicate (FTEOS), hydrogen silses quioxane (HSQ), benzo cyclo butene (BCB), tetra methyl ortho silicate (TMOS), octa methyl cyclo tetra siloxane (OMCTS), hexa methyl di siloxane (HMDS), tri methyl silyl borate (TMSB), di acetoxy ditertiary buto siloxane (DADBS), tri methyl silyl phosphate (TMSP), poly tetra fluoro ethylene (PTFE), fluoride silicate glass (FSG), polyimide nanofoams such as polypropylene oxide, carbon doped silicon oxide (CDO), organo silicate glass (OSG), SiLK amorphous fluorinated carbon, silica aerogels, silica xerogels, mesoporous silica, and/or a combination thereof.

According to an embodiment, a front side source/drain contact 170 may be disposed on the first source/drain structure 150 and/or the second source/drain structure 250. The front side source/drain contact 170 may penetrate the source/drain etch stop film 160 and be connected to at least one of the first source/drain structure 150 and/or the second source/drain structure 250. Hereinafter, to facilitate efficient understanding, an example is provided in which the front side source/drain contact 170 is connected to the first source/drain structure 150, without limitation thereto. In addition or alternately, the front side source/drain contact 170 may be connected to the first source/drain structure 150 and a source/drain structure disposed on the third source/drain region SD3 or fourth source/drain region SD4 described above. For example, the first source/drain structure 150 and the source/drain structure disposed on the third source/drain region SD3 or fourth source/drain region SD4 may be electrically connected by the front side source/drain contact 170. In an embodiment, the front side source/drain contact 170 may be disposed within the first front side interlayer insulating film 190. For example, the front side source/drain contact 170 may be surrounded by the first front side interlayer insulating film 190. In an embodiment, the first front side interlayer insulating film 190 need not cover an upper surface of the front side source/drain contact 170. For example, the upper surface of the front side source/drain contact 170 need not protrude upwards in the first direction D1 more than the upper surface of the gate structure 220. In an embodiment, the upper surface of the front side source/drain contact 170 may be placed to be flush with the upper surface of the gate structure 220. In an embodiment, the upper surface of the front side source/drain contact 170 may also be disposed to protrude upwards in the first direction D1 more than the upper surface of the gate structure 220.

A contact silicide film 155 according to an embodiment may be disposed at the front side source/drain contact 170 and the first source/drain structure 150. The contact silicide film 155 may be formed along a profile of a boundary surface between the first source/drain structure 150 and the front side source/drain contact 170. Moreover, the contact silicide film 155 may be formed irrespective of the profile of the boundary surface. In addition, the contact silicide film 155 may include a metal silicide material in an embodiment, without limitation thereto. For example, the contact silicide film 155 may include titanium silicide (TiSi2), cobalt silicide (CoSi2), nickel silicide (NiSi2), platinum silicide (PtSi), erbium silicide (ErSi2), tungsten silicide (WSi2), and the like.

In an embodiment, the front side source/drain contact 170 may include a front side source/drain contact barrier film 170a and a front side source/drain contact filling film 170b. The front side source/drain contact barrier film 170a may extend along a side surface and a bottom surface of the front side source/drain contact filling film 170b.

In an embodiment, the front side source/drain contact barrier film 170a may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. In the semiconductor device 10 according to an embodiment, the 2D material may be a metallic material and/or a semiconductor material. The 2D material may include a 2D allotrope or a 2D compound and may include, for example, at least one of graphene, molybdenum disulfide (MoS2), molybdenum diselenide (MoSe2), tungsten diselenide (WSe2), and tungsten disulfide (WS2), without limitation thereto. For example, the 2D materials described above are enumerated merely for example, and thus the 2D materials that may be included in the semiconductor device 10 according to an embodiment are not limited to the above materials. Further, in an embodiment, the front side source/drain contact filling film 170b may include, for example, at least one of aluminum (Al), tungsten (W), cobalt (Co), ruthenium (Ru), silver (Ag), gold (Au), manganese (Mn), and molybdenum (Mo).

The first front side etch stop film 196 according to an embodiment may be disposed on the first front side interlayer insulating film 190, the gate structure 220, and the front side source/drain contact 170. In addition, a second front side interlayer insulating film 191 may be disposed on the first front side etch stop film 196. For example, the first front side interlayer insulating film 190, the first front side etch stop film 196, and the second front side interlayer insulating film 191 described above may be positioned sequentially in the first direction D1. In an embodiment, the first front side etch stop film 196 may include a material having etch selectivity to the second front side interlayer insulating film 191. For example, the first front side etch stop film 196 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), aluminum oxycarbide (AlOC) and/or a combination thereof. The first front side etch stop film 196 is illustrated as, but is not limited to, a single film. In addition, unlike the drawings, the first front side etch stop film 196 need not also be formed. In an embodiment, the second front side interlayer insulating film 191 may include at least one of silicon oxide, silicon nitride, silicon carbonitride, silicon oxynitride, and a low-permittivity material.

A second front side etch stop film 197 according to an embodiment may be disposed between the second front side interlayer insulating film 191 and a third front side interlayer insulating film 192. In addition, the second front side etch stop film 197 may extend along an upper surface of the second front side interlayer insulating film 191. The second front side etch stop film 197 according to an embodiment may include a material having etch selectivity to the third front side interlayer insulating film 192. A material included in the second front side etch stop film 197 may be substantially similar to the material included in the first front side etch stop film 196 described above and a material included in the third front side interlayer insulating film 192 may be substantially similar to the material included in the second front side interlayer insulating film 191, and thus duplicated descriptions thereof are omitted.

The front side gate contact 180 according to an embodiment may be disposed on the gate structure 220. The front side gate contact 180 may penetrate the gate capping film 228. For example, the front side gate contact 180 may penetrate the gate capping film 228 and be connected to the gate electrode 222 of the gate structure 220. The front side gate contact 180 may penetrate the first front side etch stop film 196 and the second front side interlayer insulating film 191. In addition, the front side gate contact 180 may be connected to a second front side wiring line 106. In an embodiment, an upper surface of the front side gate contact 180 may protrude upwards in the first direction D1 more than the upper surface of the gate structure 220, without limitation thereto. For example, the upper surface of the front side gate contact 180 may be placed to be flush with the upper surface of the gate structure 220. In addition, the front side gate contact 180 may include a front side gate contact barrier film 180a and a front side gate contact filling film 180b. The front side gate contact barrier film 180a may surround the front side gate contact filling film 180b. A material included in the front side gate contact barrier film 180a may be substantially similar to the material included in the front side source/drain contact barrier film 170a described above and a material included in the front side gate contact filling film 180b may be substantially similar to the material included in the front side source/drain contact filling film 170b described above, and thus descriptions thereof are omitted.

In an embodiment, a first front side via 175 may be disposed on the front side source/drain contact 170 described above. The first front side via 175 according to an embodiment may be disposed within the second front side interlayer insulating film 191. The first front side via 175 may penetrate the first front side etch stop film 196 and be connected to the front side source/drain contact 170. In addition, the first front side via 175 may be connected to a first front side wiring line 105. In an embodiment, the first front side via 175 may include a first front side via barrier film 175a and a first front side via filling film 175b. In an embodiment, the first front side via barrier film 175a may extend along a side surface and a bottom surface of the first front side via filling film 175b. In an embodiment, the first front side via barrier film 175a may include at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. For example, the first front side via filling film 175b may include at least one of aluminum (Al), tungsten (W), cobalt (Co), ruthenium (Ru), copper (Cu), silver (Ag), gold (Au), manganese (Mn), and molybdenum (Mo).

In an embodiment, the first front side wiring line 105 and the second front side wiring line 106 may be disposed within the third front side interlayer insulating film 192. As described above, the first front side wiring line 105 may be connected to the first source/drain structure 150 through the first front side via 175, and the second front side wiring line 106 may be connected to the front side gate contact 180. According to an embodiment, each of the first front side wiring line 105 and the second front side wiring line 106 may include a barrier film 105a and 106a and a filling film 105b and 106b.

The first front side wiring line barrier film 105a and the second front side wiring line barrier film 106a according to an embodiment may include at least one of metal, conductive metal nitride, conductive metal carbide, conductive metal oxide, conductive metal carbonitride, and a 2D material. In addition, the first front side wiring line filling film 105b and the second front side wiring line filling film 106b according to an embodiment may include at least one of metal and metal alloy.

The first metal structure 270 and the second metal structure 280 according to an embodiment may be disposed on the first rear side interlayer insulating film 290 in the first direction D1. In addition, the rear side base pattern 101 and the element isolation film 110 may be disposed on the first rear side interlayer insulating film 290. Further, the first rear side interlayer insulating film 290 may be disposed on a second rear side interlayer insulating film 291 in the first direction D1, and the second rear side interlayer insulating film 291 may be disposed on a third rear side interlayer insulating film 292. Further, a first rear side etch stop film 296 may be formed between the first rear side interlayer insulating film 290 and the second rear side interlayer insulating film 291, and a second rear side etch stop film 297 may be formed between the second rear side interlayer insulating film 291 and the third rear side interlayer insulating film 292. The first rear side interlayer insulating film 290, the first rear side etch stop film 296, the second rear side interlayer insulating film 291, the second rear side etch stop film 297, and the third rear side interlayer insulating film 292 may be positioned sequentially in the first direction D1. For example, the first rear side interlayer insulating film 290, the second rear side interlayer insulating film 291, and the third rear side interlayer insulating film 292 may be disposed on the lower surface of the rear side base pattern 101 and may include a substantially similar material to the first front side interlayer insulating film 190, the second front side interlayer insulating film 191, and the third front side interlayer insulating film 192 described above. In addition, the first rear side etch stop film 296 and the second rear side etch stop film 297 may also be disposed on the lower surface of the rear side base pattern 101 and may include a substantially similar material to the first front side etch stop film 196 and the second front side etch stop film 197 described above.

In an embodiment, the first metal structure 270 and the second metal structure 280 may include a metal material. For example, the first metal structure 270 may include a substantially similar material to the gate electrode 222 described above, and the first metal structure 270 may include, but is not limited to, a substantially similar material to the front side source/drain contact 170 described above. In addition, unlike the drawings, the first metal structure 270 may have a multi-film consisting of a filling film and a barrier film surrounding the filling film, but illustration with regard thereto is omitted to facilitate efficient understanding.

The first metal structure 270 according to an embodiment may be disposed on the first rear side interlayer insulating film 290. For example, a lower surface of the first metal structure 270 may be placed to be flush with an upper surface of the first rear side interlayer insulating film 290. In an embodiment, the first metal structure 270 may be formed to penetrate a trench formed in the rear side base pattern 101, and accordingly, may be surrounded by the rear side base pattern 101. According to an embodiment, the first metal structure 270 may be in contact with the gate structure 220. For example, the first metal structure 270 may be in contact with the inner gate structure 220_I. In an embodiment, the first metal structure 270 may be in contact with the gate electrode 222 positioned at a lowermost portion in the first direction D1 among the gate electrodes 222 composing the inner gate structure 220_I. In this case, the first metal structure 270 may penetrate a lower surface of the gate insulating film 224 in contact with the upper surface of the rear side base pattern 101, and accordingly, the upper surface of the first metal structure 270 may be in contact with a lower surface of the gate electrode 222 positioned at the lowermost portion.

Further, in an embodiment, the first metal structure 270 may have a shape with an increasing width toward the lower surface of the rear side base pattern 101 in the first direction D1. For example, the first metal structure 270 may have a substantially tapered shape in which a width increases from an upper portion thereof toward a lower portion, but the present disclosure is not limited to these examples. In an embodiment, the first metal structure 270 may be provided to be plural in number. Some of the plurality of first metal structures 270 may function as a rear side gate contact and others may function as an alignment structure. Moreover, substantially all of the first metal structures 270 may also function as the rear side gate contact, without limitation thereto.

According to an embodiment, the first metal structure 270 may include a first gate rear side structure 271, a second gate rear side structure 272, and a third gate rear side structure 273. The first gate rear side structure 271, the second gate rear side structure 272, and the third gate rear side structure 273 according to an embodiment may be disposed to be spaced apart in the second direction D2. For example, the first rear side source/drain contact 281, as may be described in greater detail below, may be disposed between the first gate rear side structure 271 and the second gate rear side structure 272 in the second direction D2, and the second rear side source/drain contact 282, as may be described in greater detail below. may be disposed between the second gate rear side structure 272 and the third gate rear side structure 273 in the second direction D2.

In an embodiment, a lower surface of the first gate rear side structure 271. 272 or 273 and the upper surface of the first rear side interlayer insulating film 290 may be in contact. In addition, a lower portion of the gate rear side structure 271, 272 or 273 may be spaced apart from the second metal structure 280, 281 or 282 by a predetermined distance in the second direction D2.

As described above, the second gate rear side structure 272 according to an embodiment may be positioned between the first rear side source/drain contact 281 and the second rear side source/drain contact 282. In addition, a lower portion of the second gate rear side structure 272 may be spaced apart from the second metal structure 280 by a predetermined distance in the second direction D2. For example, the second gate rear side structure 272 may be spaced apart from each of the first rear side source/drain contact 281 disposed at one side and the second rear side source/drain contact 282 disposed at the other side. The second gate rear side structure 272 may be connected to a first via connection part 265 disposed below in the first direction D1. The first via connection part 265 according to an embodiment may be electrically connected to a first rear side wiring line 305 through a first rear side via 275. For example, the first via connection part 265 may be disposed within the first rear side interlayer insulating film 290. An upper surface of the first via connection part 265 may be in contact with a lower surface of the second gate rear side structure 272. In addition, the first rear side via 275 may be disposed within the second rear side interlayer insulating film 291 and may penetrate the first rear side etch stop film 296 and be connected to the first via connection part 265. Further, the first rear side wiring line 305 may be disposed within the third rear side interlayer insulating film 292 and may penetrate the second rear side etch stop film 297 and be connected to the first rear side via 275. For example, the second gate rear side structure 272 may be electrically connected to the first rear side wiring line 305 through the first via connection part 265 and the first rear side via 275, and accordingly, may function as the rear side gate contact. However, not limited to the above examples, in an embodiment, the semiconductor device 10 may also include any one alone of the first via connection part 265 and the first rear side via 275.

In addition, according to an embodiment, each of the first via connection part 265, the first rear side via 275, and the first rear side wiring line 305 may include a barrier film 265a, 275a, and 305a and/or a filling film 265b, 275b, and 305b. The first via connection part barrier film 265a may extend along a side surface and an upper surface of the first via connection part filling film 265b, and the first rear side via barrier film 275a may extend along a side surface and an upper surface of the first rear side via filling film 275b, and the first rear side wiring line barrier film 305a may extend along a side surface and an upper surface of the first rear side wiring line filling film 305b. The first via connection part barrier film 265a and the first rear side via barrier film 275a may be substantially similar to the first front side via barrier film 175a described above, and at least some or most of the first via connection part filling film 265b and the first rear side via filling film 275b may be substantially similar to the first front side via filling film 175b described above. In addition, the first rear side wiring line barrier film 305a and the first rear side wiring line filling film 305b may be substantially similar to the first front side wiring line barrier film 105a and the first front side wiring line filling film 105b described above.

A first blocking film 287 according to an embodiment may be formed at a lower portion of the rear side base pattern 101. In an embodiment, the first blocking film 287 may surround at least a portion of the first metal structure 270. For example, the first blocking film 287 may surround lower portions of the first gate rear side structure 271, the second gate rear side structure 272, and the third gate rear side structure 273. For example, a lower side surface of each of the first gate rear side structure 271, the second gate rear side structure 272, and the third gate rear side structure 273 may be surrounded by the first blocking film 287. For example, the first blocking film 287 may be interposed between a second blocking film 283 and 284, as may be described in greater detail below, and the first metal structure 270. In this case, a lower surface of each of the first gate rear side structure 271, the second gate rear side structure 272, and the third gate rear side structure 273 need not be surrounded by the first blocking film 287. In an embodiment, a lower surface of the first blocking film 287 may be placed to be flush with the upper surface of the first rear side interlayer insulating film 290. For example, the lower surface of the first blocking film 287 may be on the substantially same level as the upper surface of the first rear side interlayer insulating film 290. In addition, the lower surface of the first blocking film 287 may be positioned on the substantially same level as the lower surface of each of the first gate rear side structure 271, the second gate rear side structure 272, and the third gate rear side structure 273. The first blocking film 287 according to an embodiment may include oxide. For example, the first blocking film 287 may include silicon oxide and hydroxide.

In an embodiment, the first blocking film 287 surrounding the first gate rear side structure 271 may be in contact with the first liner 283, as may be described in greater detail below, at one side. In addition, the first blocking film 287 surrounding the second gate rear side structure 272 may be in contact with the first liner 283 at one side and in contact with the second liner 284 at another side. Further, the first blocking film 287 surrounding the third gate rear side structure 273 may be in contact with the second liner 284 at one side. For example, the lower surface of the first gate rear side structure 271 may be surrounded by the first rear side interlayer insulating film 290, and a portion, such as an upper side surface, of a side surface of the first gate rear side structure 271 may be surrounded by the gate insulating film 224, and another portion of the side surface of the first gate rear side structure 271 may be surrounded by the rear side base pattern 101, and yet another portion, such as a lower side surface, of the side surface of the first gate rear side structure 271 may be surrounded by the first blocking film 287, and an upper surface of the first gate rear side structure 271 may be in contact with the gate electrode 222. In an embodiment, as described above, the lower surface of the second gate rear side structure 272 may be in contact with the first via connection part 265, and a side surface of the second gate rear side structure 272 may be surrounded in a structure substantially similar to the side surface of the first gate rear side structure 271, and an upper surface of the second gate rear side structure 272 may be in contact with another gate electrode 222 spaced apart from the gate electrode 222 in contact with the first gate rear side structure 271 in the second direction D2.

The second metal structure 280 according to an embodiment may be positioned in the second direction D2 with the first metal structure 270 as described above. In addition, the second metal structure 280 may be spaced apart from the first metal structure 270 by a predetermined distance. The second metal structure 280 may be disposed between the source/drain structures 150 and 250 and the first rear side interlayer insulating film 290 in the first direction D1.

In an embodiment, the second metal structure 280 may include the first rear side source/drain contact 281 and the second rear side source/drain contact 282. The first rear side source/drain contact 281 may be disposed between the first gate rear side structure 271 and the second gate rear side structure 272, and the second rear side source/drain contact 282 may be disposed between the second gate rear side structure 272 and the third gate rear side structure 273. For example, the first gate rear side structure 271, the first rear side source/drain contact 281, the second gate rear side structure 272, the second rear side source/drain contact 282, and the third gate rear side structure 273 may be positioned sequentially in the second direction D2 and may be spaced apart from each other.

In an embodiment, the first rear side source/drain contact 281 may be positioned to overlap the first source/drain structure 150 in the first direction D1. In addition, the first rear side source/drain contact 281 may be in contact with the first source/drain structure 150. For example, an upper surface of the first rear side source/drain contact 281 may be in contact with the lower surface of the first source/drain structure 150. Accordingly, the first rear side source/drain contact 281 may be electrically connected to the first source/drain structure 150. In addition, the upper surface of the first rear side source/drain contact 281 may be on a different level from the upper surface of the first metal structure 270. For example, since the vertical level from the lower surface of the rear side base pattern 101 to the lower surface of the first source/drain structure 150 may be greater than the vertical level to the lowermost surface of the gate structure 220 as described above, the upper surface of the first rear side source/drain contact 281 may be positioned above the upper surface of the first metal structure 270 in the first direction D1. In an embodiment, a lower surface of the first rear side source/drain contact 281 may be positioned on the substantially same level as the lower surface of the first blocking film 287 and the lower surface of the first metal structure 270.

According to an embodiment, the second rear side source/drain contact 282 may overlap and be in contact with the second source/drain structure 250 in the first direction D1. Accordingly, the second rear side source/drain contact 282 may be electrically connected to the second source/drain structure 250. For example, an upper surface of the second rear side source/drain contact 282 may be in contact with the lower surface of the second source/drain structure 250 and may be on the substantially same level as the lower surface of the first blocking film 287 and the lower surface of the first metal structure 270. In addition, the upper surface of the second source/drain structure 250 may be on a different level from the upper surface of the first metal structure 270. In an embodiment, the upper surface of the second rear side source/drain contact 282 may be positioned above the upper surface of the first metal structure 270 in the first direction D1, similar to the first rear side source/drain contact 281.

In an embodiment, the second blocking film 283 and 284 may be formed on each side surface of the first rear side source/drain contact 281 and the second rear side source/drain contact 282. In an embodiment, the second blocking film 283 and 284 may include silicon. For example, the second blocking film 283 and 284 may include, but is not limited to, silicon nitride (SiN).

According to an embodiment, the second blocking film 283 and 284 may include the first liner 283 and the second liner 284. The first liner 283 according to an embodiment may surround the side surface of the first rear side source/drain contact 281. In addition, the second liner 284 may surround the side surface of the second rear side source/drain contact 282. In an embodiment, a lower surface of the first liner 283 may be flush with, in other words on the substantially same level as, each of the lower surface of the first rear side source/drain contact 281, the upper surface of the first rear side interlayer insulating film 290, the lower surface of the first metal structure 270, and the lower surface of the first blocking film 287. In addition, similarly, a lower surface of the second liner 284 may also be on the substantially same level as the lower surface of the first rear side source/drain contact 281 and a lower surface of the second rear side source/drain contact 282.

In an embodiment, an upper surface of the first liner 283 may be positioned on the substantially same level as the upper surface of the first rear side source/drain contact 281 and may be in contact with the lower surface of the first source/drain structure 150. Accordingly, an upper portion of a side surface of the first liner 283 may be in contact with a portion of a side surface of the gate structure 220, and a lower portion of the side surface of the first liner 283 may be in contact with a side surface of the first blocking film 287, and the other portion of the side surface of the first liner 283 may be in contact with the rear side base pattern 101. Further, in an embodiment, an upper surface of the second liner 284 may be positioned on the substantially same level as the upper surface of the second rear side source/drain contact 282 and may be in contact with the lower surface of the second source/drain structure 250. Accordingly, an upper portion of a side surface of the second liner 284 may be in contact with a portion of the side surface of the gate structure 220, and a lower portion of the side surface of the second liner 284 may be in contact with the first blocking film 287, and the other portion of the side surface of the second liner 284 may be in contact with the rear side base pattern 101.

In an embodiment, the first rear side source/drain contact 281 and the second rear side source/drain contact 282 may be connected to a second via connection part 266 disposed within the first rear side interlayer insulating film 290. The second via connection part 266 may include a second via connection part barrier film 266a and a second via connection part filling film 266b. The second via connection part barrier film 266a may cover an upper surface and a side surface of the second via connection part filling film 266b. Further, in an embodiment, at least one second via connection part 266 may be disposed within the second rear side interlayer insulating film 291 and connected to a second rear side via 276 penetrating the first rear side etch stop film 296. In addition, the second via connection part 266 may be disposed within the third rear side interlayer insulating film 292 and connected to a second rear side wiring line 306 penetrating the second rear side etch stop film 297. The second via connection part 266 may include the barrier film 266a and the filling film 266b, and the second rear side wiring line 306 may include a barrier film 306a and a filling film 306b. However, unlike the above descriptions, in an embodiment, any one alone of the second via connection part 266 and the second rear side via 276 may also be provided.

According to an embodiment described above, the lower surface of the first metal structure 270 connected to the gate structure 220 may be in contact with the upper surface of the first rear side interlayer insulating film 290, a lower portion of a side surface thereof may be surrounded by the first blocking film 287, and the other portion of the side surface thereof may be surrounded by the rear side base pattern 101. Further, in the second metal structure 280, a portion (for example, side surface) excluding an upper surface of the second metal structure 280 connected to the source/drain structures 150 and 250 and a lower surface of the second metal structure 280 connected to the second via connection part 266 may be surrounded by the second blocking film 283 and 284. Accordingly, in an embodiment, conduction may be prevented between some of the first metal structures 270 functioning as the rear side gate contact and the second metal structure 280 functioning as the rear side source/drain contact. For example, since electrical connection may be blocked between the first metal structure 270 and the second metal structure 280 by the first blocking film 287 and the second blocking film 283 and 284, electrical short or leakage current may be minimized and electrical reliability of the semiconductor device 10 may be improved.

In addition, the upper surface of the second metal structure 280 described above may be disposed above the upper surface of the first metal structure 270 and the lowermost surface of the gate structure 220 in the first direction D1, and accordingly, the second blocking film 283 and 284 need not only surround the side surface of the rear side base pattern 101 surrounding the first metal structure 270 but also a portion of the side surface of the gate structure 220, and therefore, conduction between the first metal structure 270 and the second metal structure 280 may be blocked more thoroughly.

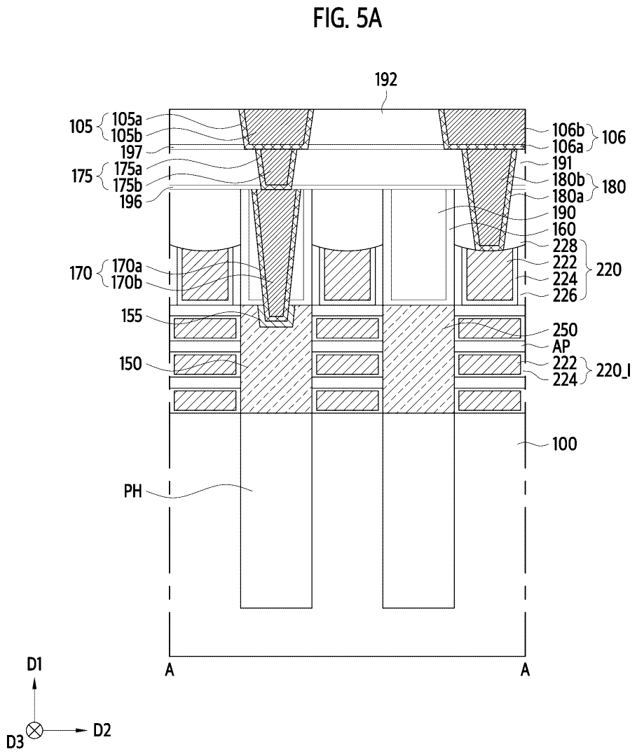

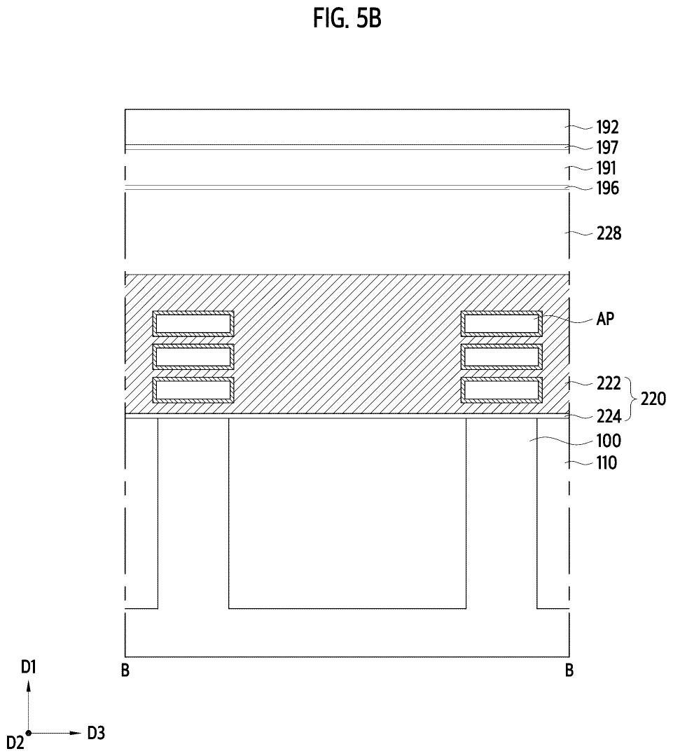

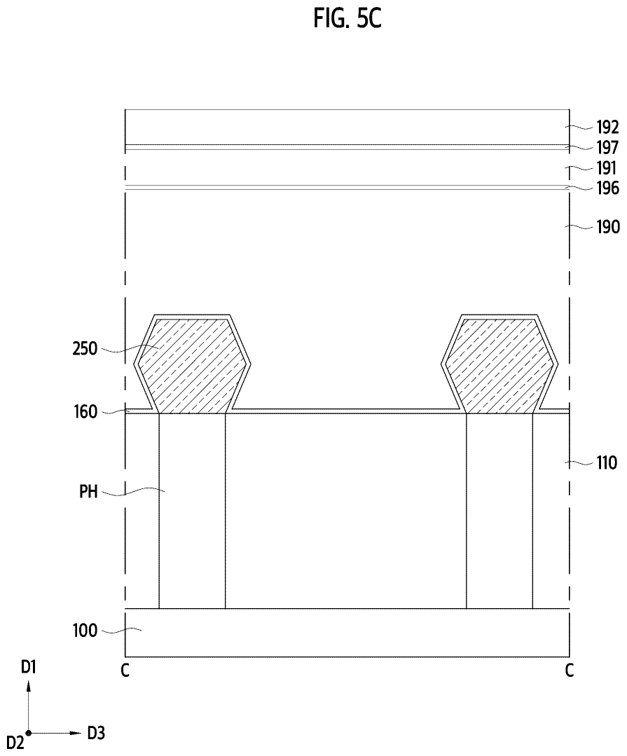

FIGS. 5 to 13 are diagrams illustrating intermediate stages in a method of manufacturing the semiconductor device of FIG. 1. Hereinafter, a method of manufacturing the semiconductor device 10 described with reference to FIGS. 1 to 4 is described in detail with reference to FIGS. 5 to 13. In addition, the size and arrangement may be exaggerated or any element may also be omitted to facilitate efficient understanding in FIGS. 5 to 13. Further, hereinafter, reference numerals used in FIGS. 1 to 4 may be used for substantially the same or like elements—. Moreover, substantially duplicate description may be omitted.

In addition, FIGS. 5A to 13A are diagrams showing a cross-section taken along line A-A of FIG. 1 for each stage in the manufacturing method, and FIGS. 5B to 13B are diagrams showing a cross-section taken along line B-B of FIG. 1 for each stage in the manufacturing method, and FIGS. 5C to 13C are diagrams showing a cross-section taken along line C-C of FIG. 1 for each stage in the manufacturing method.

Referring to FIGS. 5A to 5C, according to an embodiment, the semiconductor device 10 in which the gate structure 220 and the source/drain structures 150 and 250 may be formed may be provided. In addition, a substrate 100, the element isolation film 110, and a placeholder PH may be formed below the gate structure 220 and the source/drain structures 150 and 250 in the first direction D1. For example, the placeholder PH according to an embodiment may be formed below the source/drain structures 150 and 250 in the first direction D1. For example, each of the first source/drain structure 150 and the second source/drain structure 250 may overlap the placeholder PH in the first direction D1, and each of the lower surface of the first source/drain structure 150 and the lower surface of the second source/drain structure 250 may be in contact with an upper surface of the placeholder PH. In an embodiment, the placeholder PH may be disposed at a portion where the second metal structure 280 is formed in the following manufacturing process. For example, the placeholder PH overlapping the first source/drain structure 150 in the first direction D1 among the placeholders PH may secure a space for the first rear side source/drain contact 281 to be formed, and the placeholder PH overlapping the second source/drain structure 250 in the first direction D1 among the placeholders PH may secure a space for the second rear side source/drain contact 282 to be formed. According to an embodiment, the placeholder PH may include, but is not limited to, silicon (Si), germanium (Ge), silicon-germanium (SiGe), and silicon carbide (SiC).

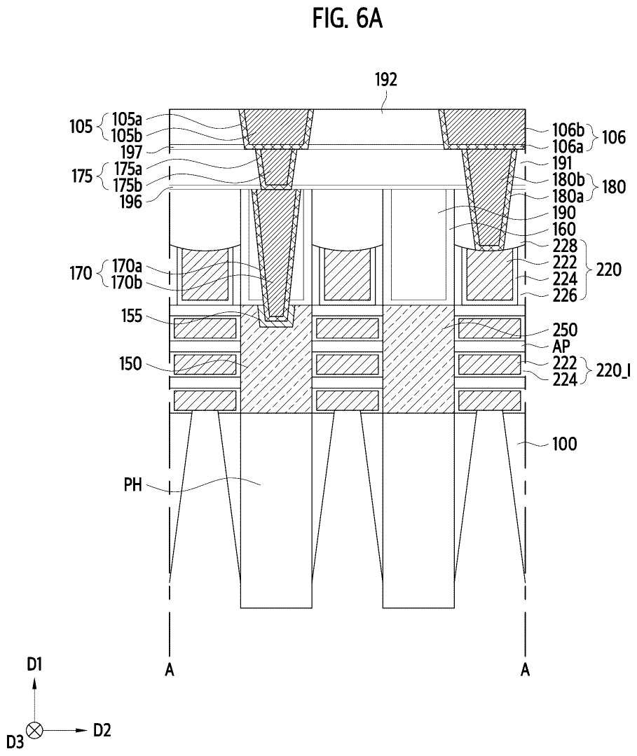

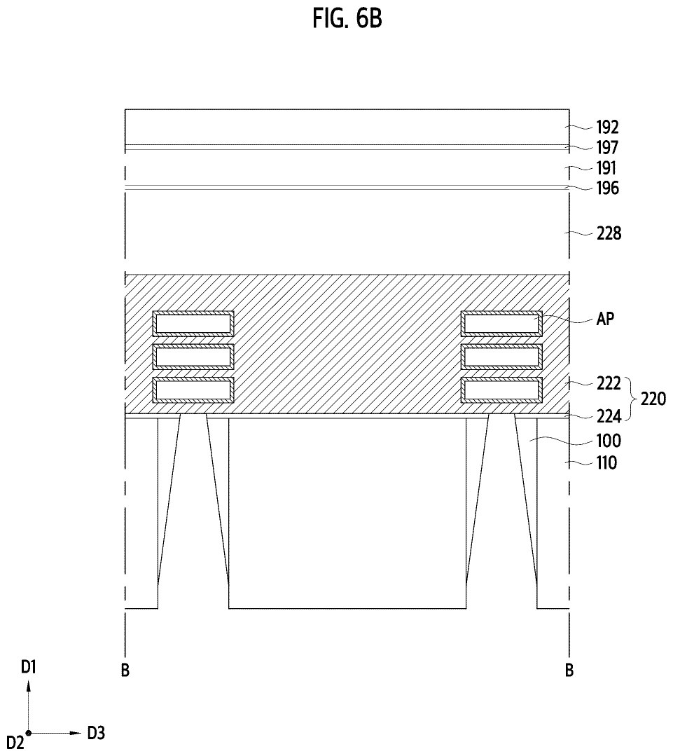

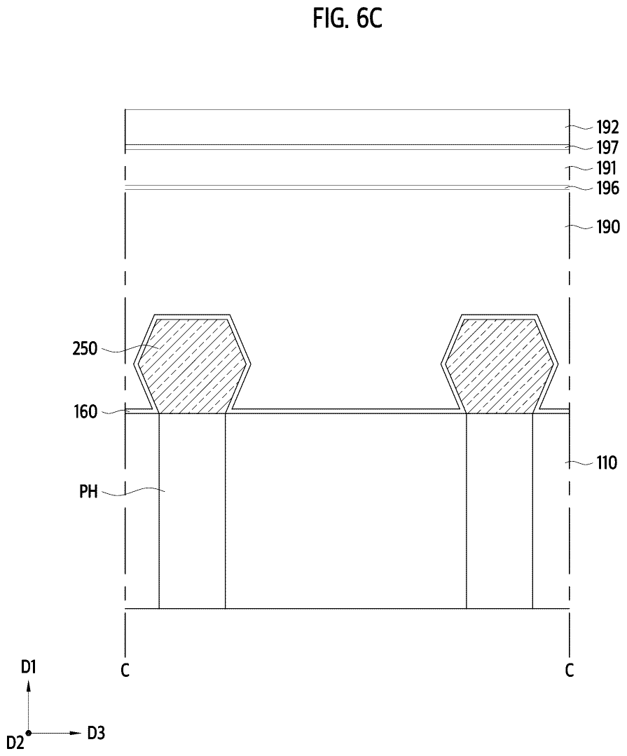

Referring to FIGS. 6A to 6C, a partial region of the substrate 100 according to an embodiment may be etched. For example, in an embodiment, selective wet etching may be conducted using a crystal structure of a material included in the substrate 100. For example, when the substrate 100 includes silicon, the partial region of the substrate 100 may be etched using a property that etching speeds are different depending on a crystal plane of the substrate 100 based on a crystal structure of silicon. For example, selective etching may be conducted by the silicon material of the substrate 100 reacting with OH-ion, and in this case, an etchant including at least one of tetramethylammonium hydroxide (TMAH), ammonia, and potassium hydroxide (KOH) may be mainly used. Accordingly, the substrate 100 between the placeholders PH may be selectively etched, and the etching depth and width of the substrate 100 may be controlled depending on etching time, temperature, and concentration of a solution, and the angle and size of the partial region formed according thereto may be adjusted depending on design requirements. Here, the partial region may be defined as a region where the first metal structure 270 is formed. In addition, the partial region may be a region where the gate structure 220 is overlapped therewith in the first direction D1. In an embodiment, the substrate 100 may be etched so that an upper surface of the partial region may be flush with the lower surface of the gate electrode 222 positioned at the lowermost portion of the gate structure 220. In addition, the partial region may have a substantially tapered shape. For example, the partial region may have a shape with an increasing width as being farther from the gate structure 220 in the first direction D1. Further, as illustrated in FIG. 6A and the like, the partial region may have a shape with the width thereof increasing farther from the gate structure 220 and the width thereof being uniform by the placeholder PH when reaching a lower portion, without limitation thereto.

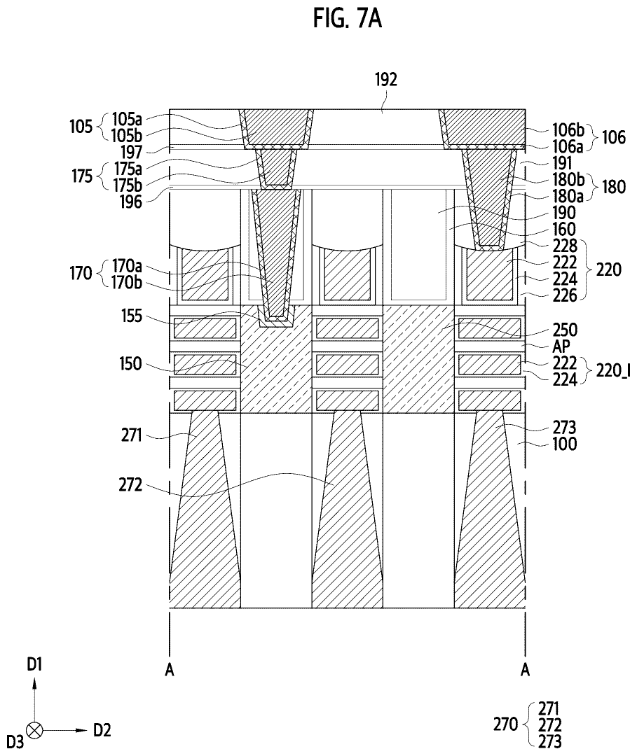

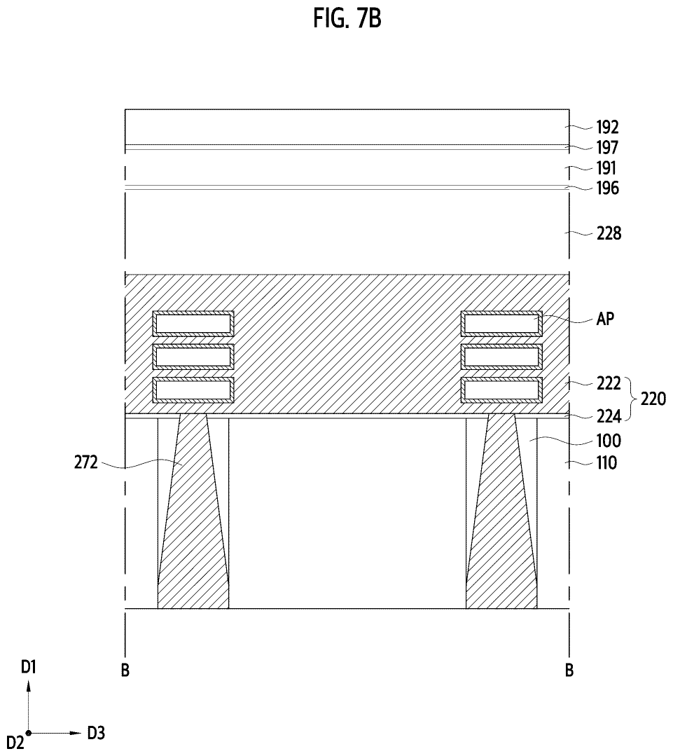

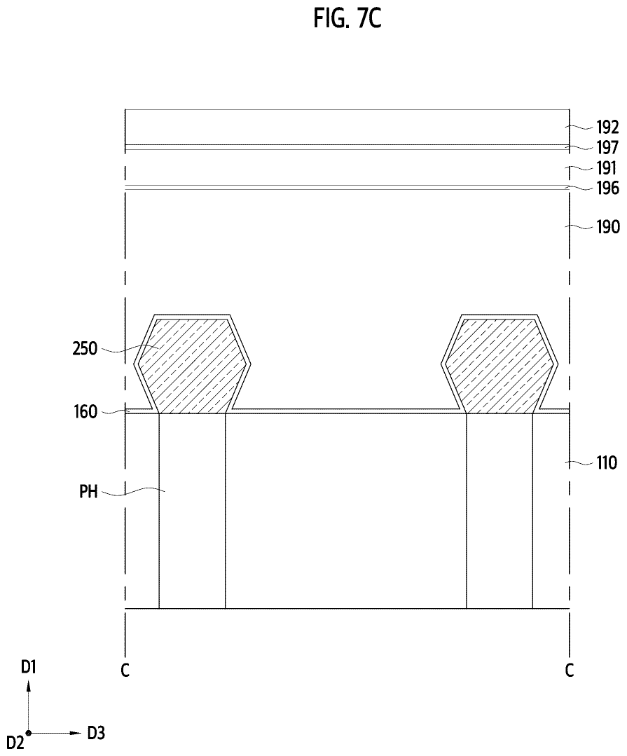

Referring to FIGS. 7A to 7C, the partial region formed in the intermediate stages of the manufacturing method described above may be filled with a metal material by performing chemical vapor deposition (CVD) or an electroplating process. Here, since the metal material, for example, may be substantially similar to the material included in the first metal structure 270 described above, duplicated descriptions thereof are omitted. Further, in an embodiment, by performing a chemical mechanical polishing (CMP) process after filling the partial region with the metal material, the deposited metal material protruding from the placeholder PH may be removed. For example, a lower surface formed by the metal material filling the partial region may be planarized to be flush with a lower surface of the placeholder PH through the CMP process. Accordingly, in an embodiment, an upper surface formed by the metal material filling the partial region may be in contact with the lower surface of the gate electrode 222. In addition, a side surface formed by the metal material filling the partial region may be surrounded by the substrate 100. In an embodiment, when supposing that three partial regions are formed, one of the metal materials filling each partial region may be the first gate rear side structure 271, another may be the second gate rear side structure 272, and yet another may be the third gate rear side structure 273. Further, in this case, a margin in the first direction D1 may be formed between a lowermost end of the metal material filling the partial region and a lowermost end of an outer side surface of the metal material filling the partial region contacting the substrate 100. The margin may perform a role as a buffer in the following process of removing the placeholder PH. For example, the corresponding margin may perform a role as a buffer so that the substrate 100 is not etched when removing the placeholder PH later. This may be described in greater detail below.

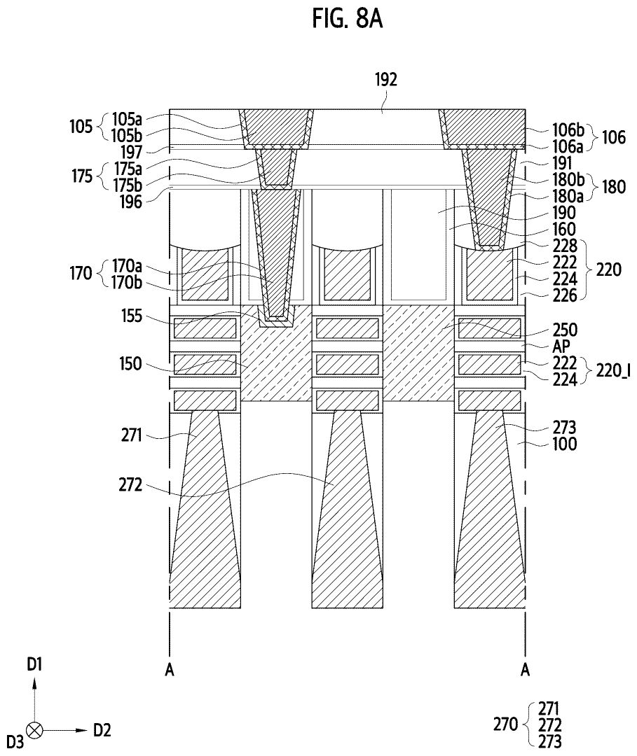

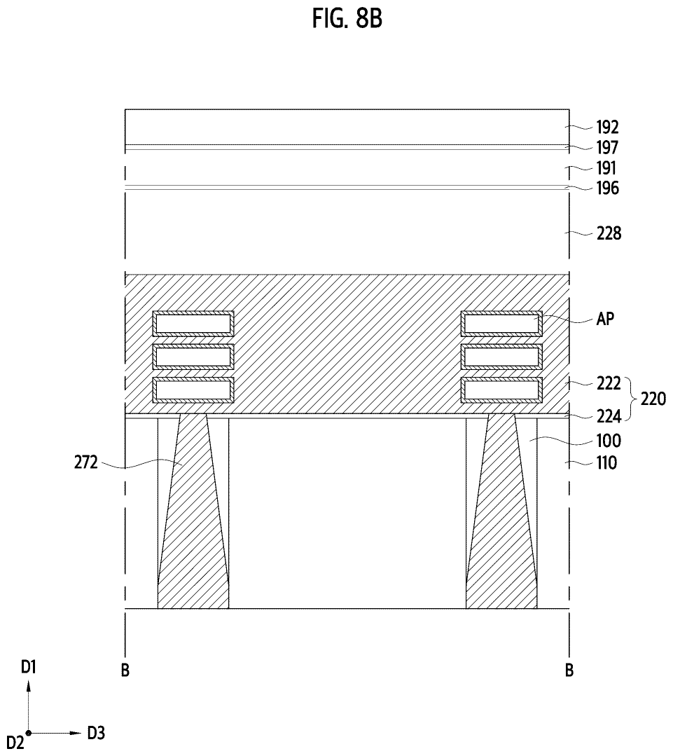

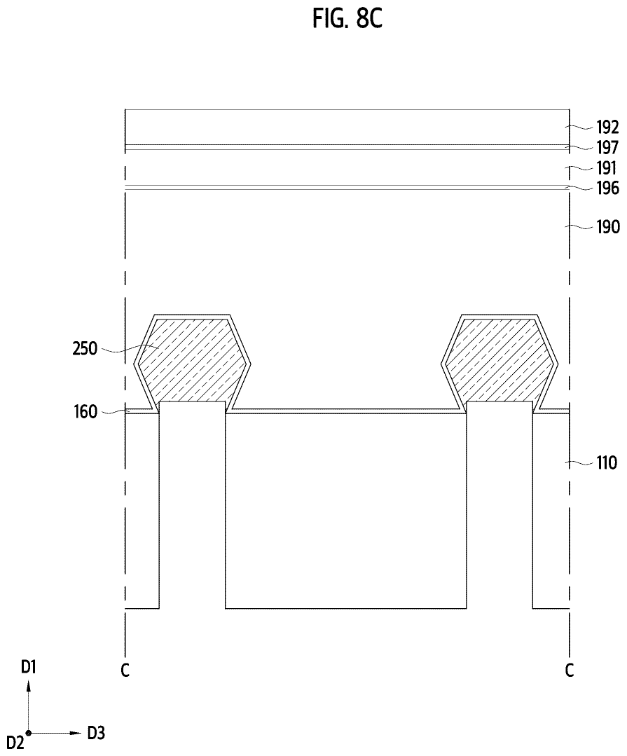

Referring to FIGS. 8A to 8C, according to an embodiment, the placeholder PH may be removed subsequently. For example, the placeholder PH, which is a temporary structure arranged to form the second metal structure 280 may be selectively removed through an etching process. For example, the placeholder PH may be removed through a wet etching process, without limitation thereto. For example, the placeholder PH may also be removed through dry etching using plasma. For example, when the placeholder PH is removed through wet etching, the placeholder PH may be selectively removed by a SC-1(NH4OH+H2O2+H2O) etchant, For example, as a silicon-germanium material included in the placeholder PH is oxidized by H2O2 and dissolved by NH4OH. In still other an embodiment, when the placeholder PH is removed through dry etching, nitrogen trifluoride (NF3) etching gas may be used as an example of process gas using a capacitively-coupled plasma (CCP) device. For example, in this case, a high-frequency voltage may be applied to at least one of two electrodes positioned at each of an upper portion and a lower portion of CCP, and nitrogen trifluoride gas may be excited and plasma may be generated, and fluorine radical (F radical) may be generated, and the placeholder PH including silicon-germanium may react with fluorine radical and be removed. In this case, since the substrate 100 may include silicon as described above, the placeholder PH including silicon-germanium having a selectivity ratio equal to or greater than 300:1 compared to silicon may be selectively etched. In addition, since the margin in the first direction D1 is secured in the substrate 100 by the metal material composing the first to third gate rear side structures 271, 272, and 273 as described above, it may be minimized that the substrate 100 is etched by the etchant while performing the etching process. Further, in an embodiment, by exposing the semiconductor device 10 further to the etchant after the placeholder PH is entirely removed, the first source/drain structure 150 and the second source/drain structure 250 may be recessed. For example, so that the lower surface of the first source/drain structure 150 and the lower surface of the second source/drain structure 250 are positioned above the lowermost surface of the gate structure 220 in the first direction D1, lower portions of the first source/drain structure 150 and the second source/drain structure 250 may be etched.

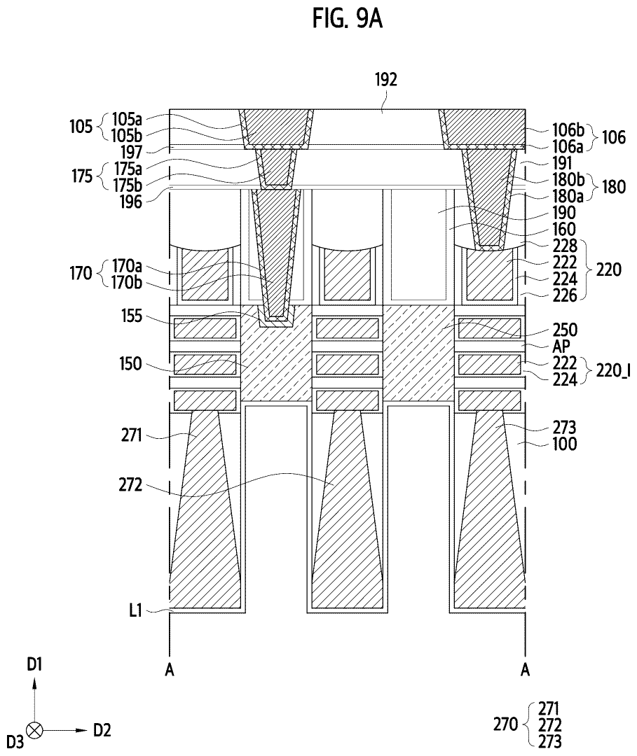

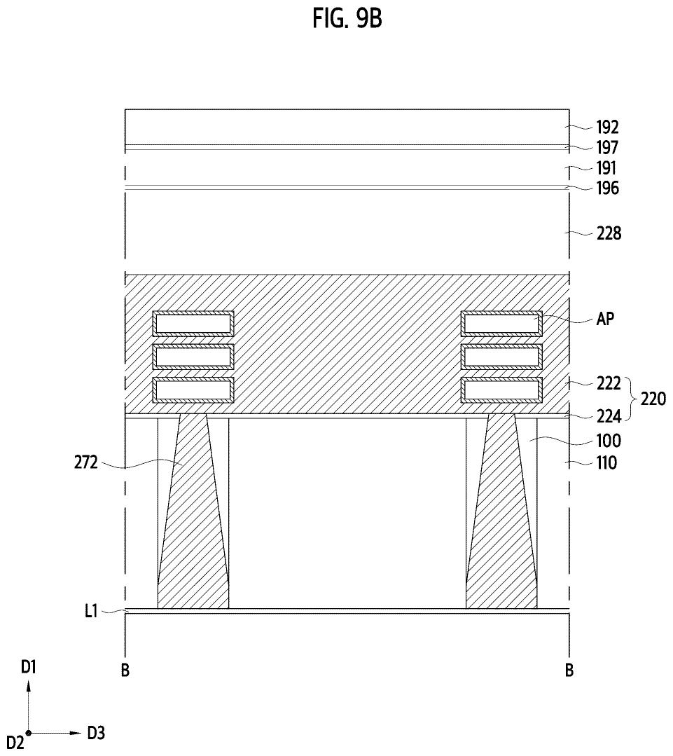

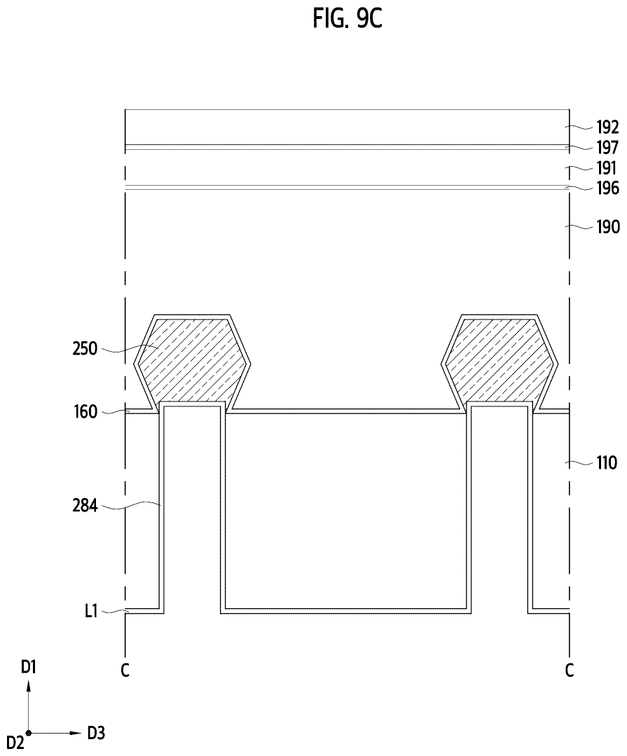

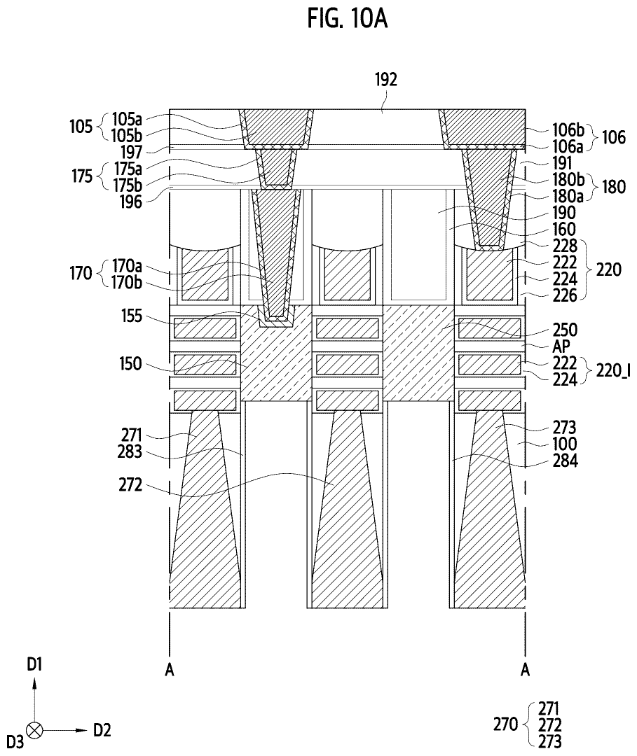

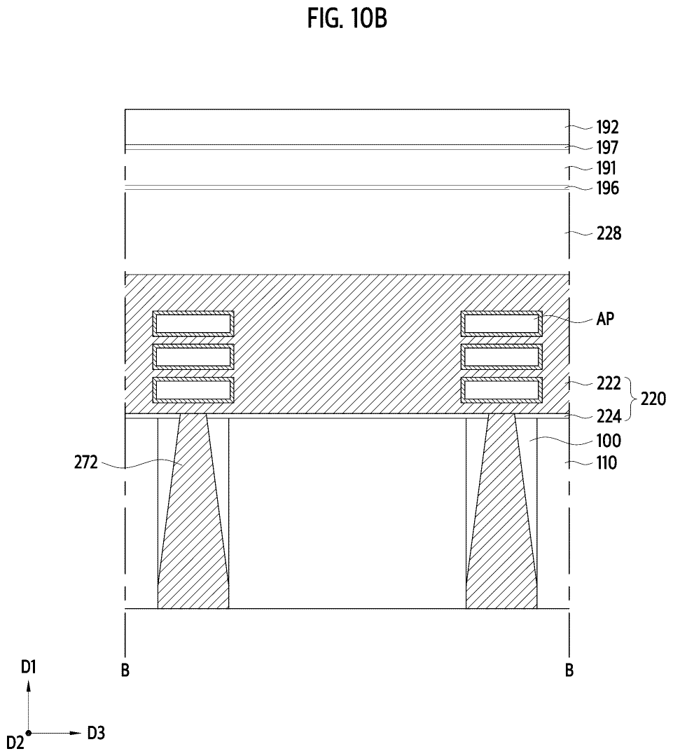

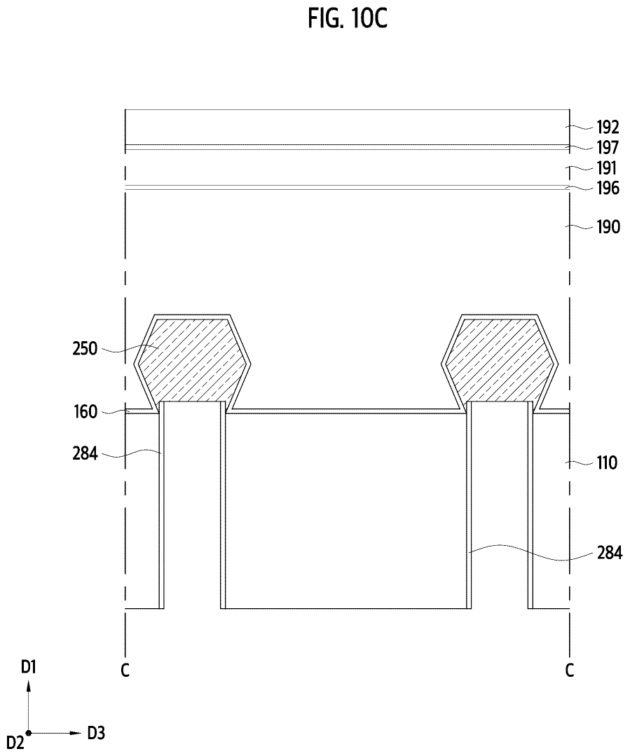

Referring to FIGS. 9A to 9C and FIGS. 10A to 10C, in an embodiment, a first deposition layer L1 may be deposited on the upper surface and a side surface of the element isolation film 110 corresponding to a portion where the upper surfaces of the first to third gate rear side structures 271, 272, and 273, a partial side surface of the substrate 100, and the placeholder PH, such as in FIG. 8A, are removed. For example, the first deposition layer L1 may be deposited on an entire area of a lower surface composing the semiconductor device 10. In an embodiment, the first deposition layer L1 may include silicon nitride. Subsequently, in an embodiment, a portion of the first deposition layer L1 may be removed through an etching process. For example, in the first deposition layer L1, the first deposition layer L1 deposited on the lower surfaces of the first to third gate rear side structures 271, 272, and 273 and the first deposition layer L1 deposited on the lower surfaces of the first source/drain structure 150 and the second source/drain structure 250 may be removed. Accordingly, the first deposition layer L1 remaining between a lower portion of the first gate rear side structure 271 and the substrate 100 surrounding the first gate rear side structure 271 and a lower portion of the second gate rear side structure 272 and the substrate 100 surrounding the second gate rear side structure 272 may function as the first liner 283 described above. In addition, the first deposition layer L1 remaining between the substrate 100 surrounding the lower portion of the second gate rear side structure 272 and the second gate rear side structure 272 and the substrate 100 surrounding a lower portion of the third gate rear side structure 273 and the third gate rear side structure 273 may function as the second liner 284 described above. In this case, the upper surface of the first liner 283 and the upper surface of the second liner 284 may be in contact with the lower surface of the first source/drain structure 150 and the lower surface of the second source/drain structure 250 respectively.

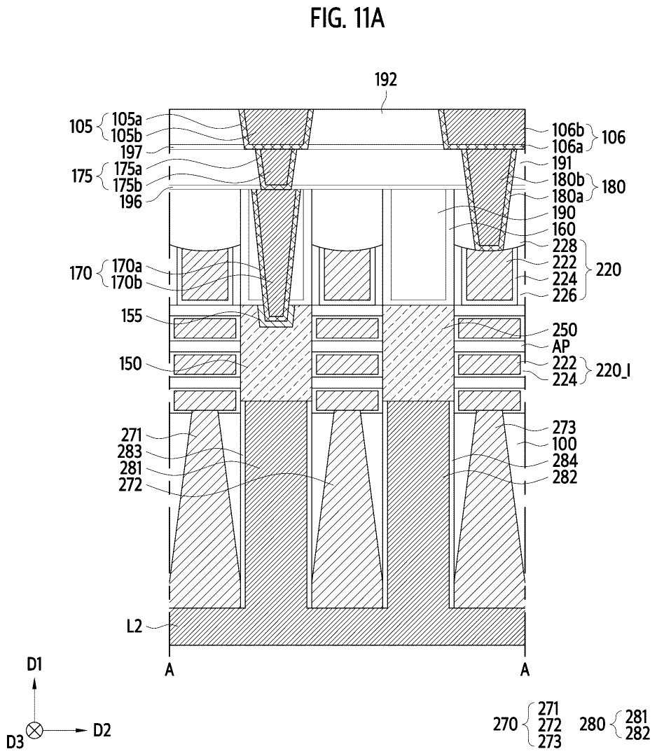

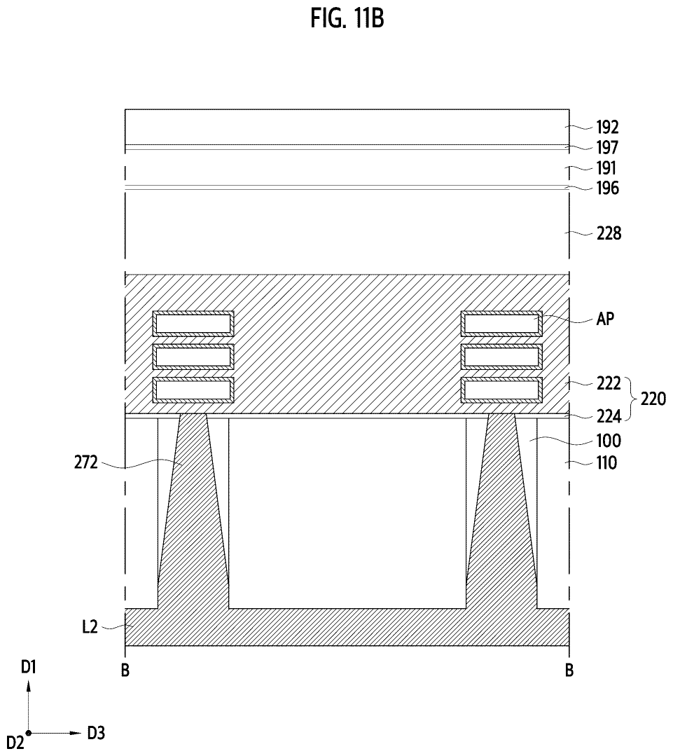

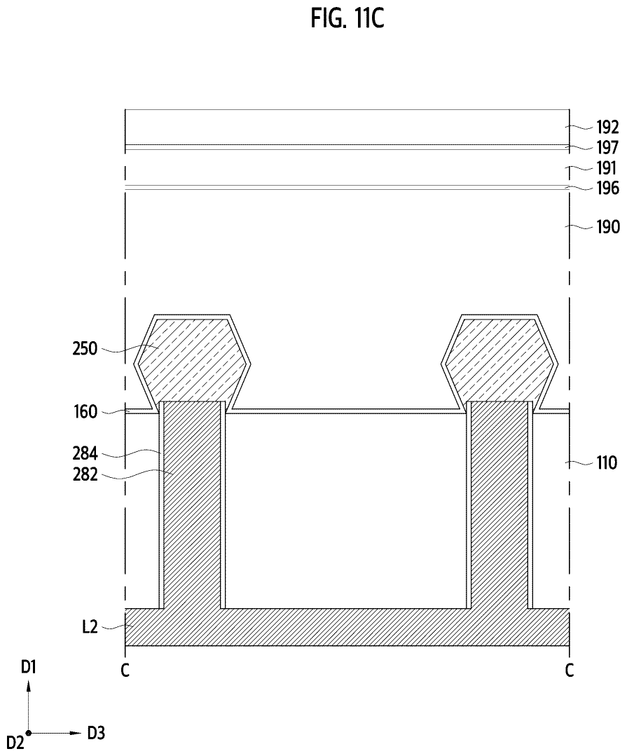

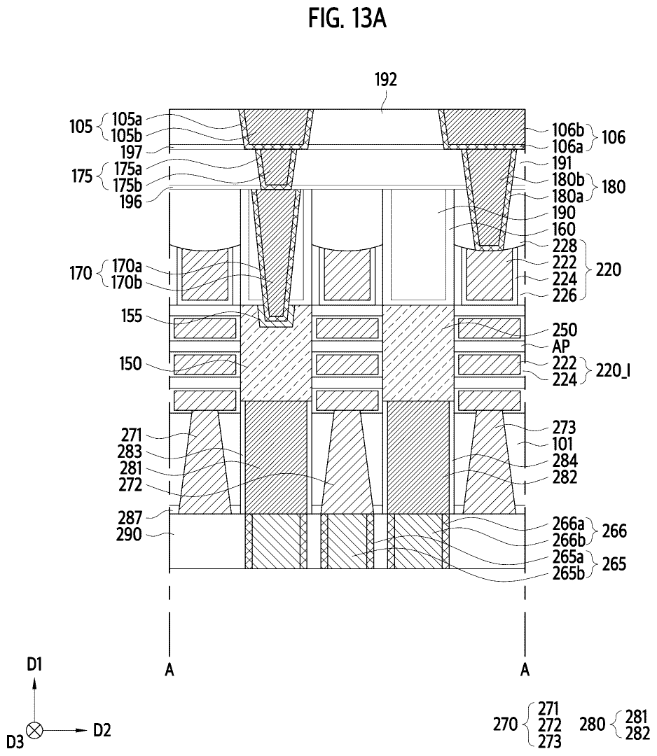

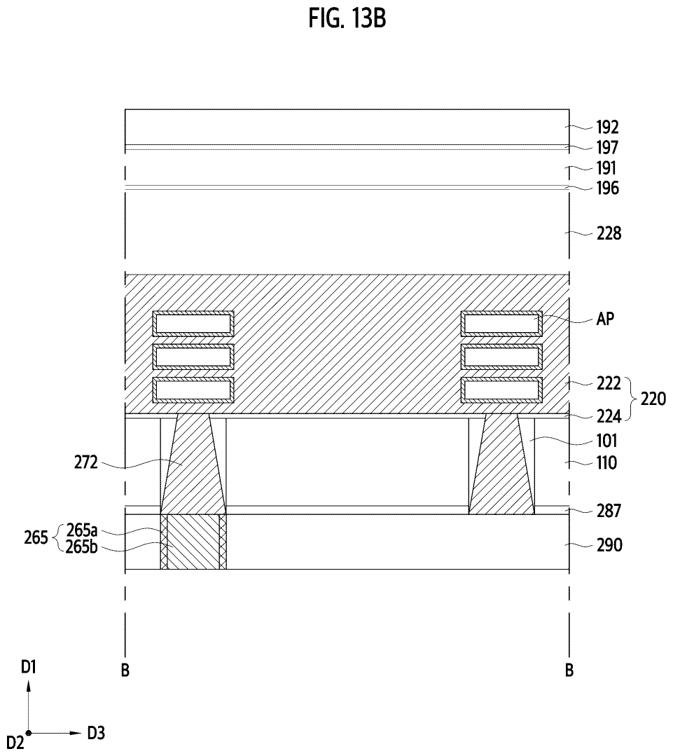

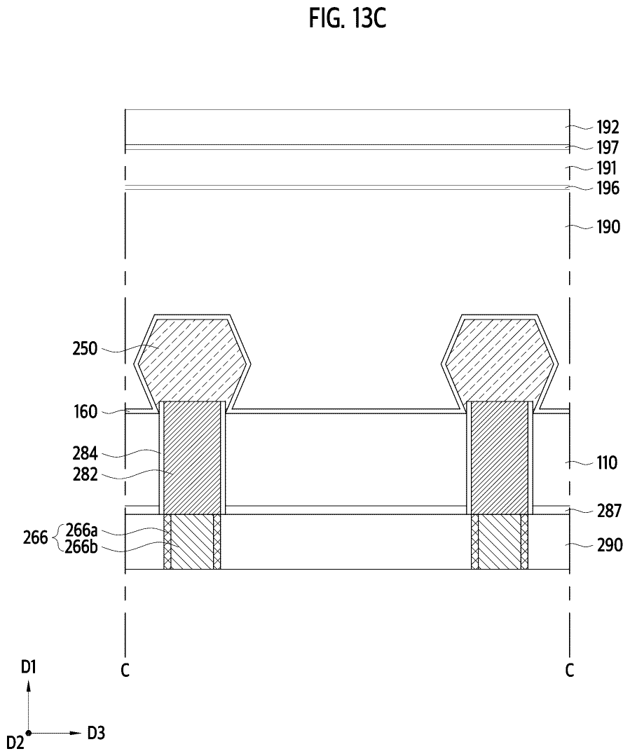

Referring to FIGS. 11A to 11C, a second deposition layer L2 may be formed by filling the entire area of the lower surface composing the semiconductor device 10 with a metal material. In this process, similarly to the above descriptions, the metal material may be filled through the CVD process or electroplating process. Accordingly, each space between the first liner 283 and the second liner 284 may be filled with the metal material, and the second deposition layer L2 filling each of the liners 283 and 284 may function as the first rear side source/drain contact 281 and the second rear side source/drain contact 282 described above through intermediate stages illustrated in FIGS. 13A to 13C. Accordingly, the metal material filling each of the liners 283 and 284 may be substantially the same or identical to the material included in the second metal structure 280 described above.

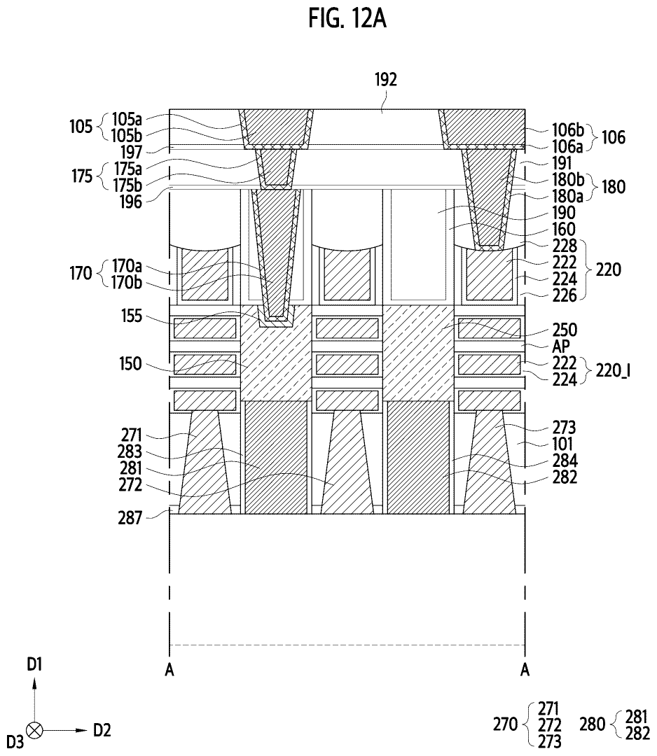

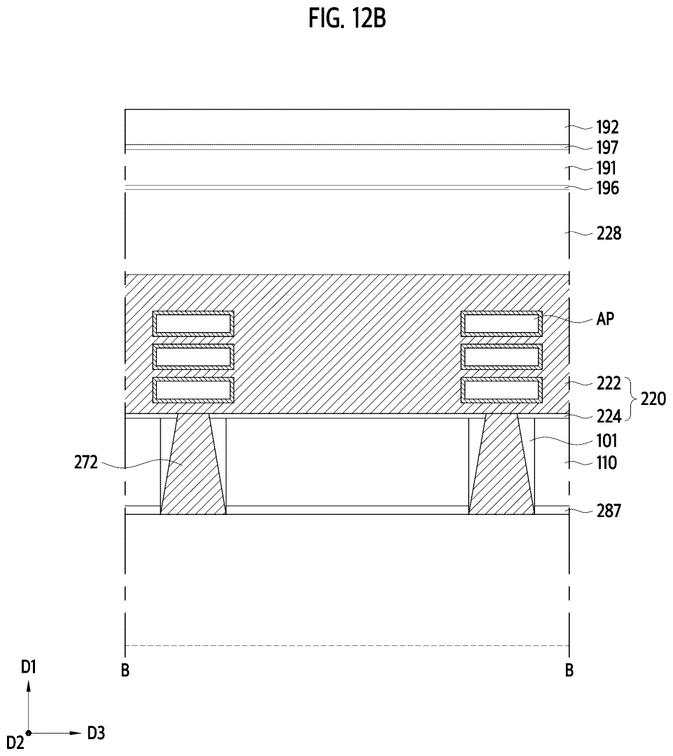

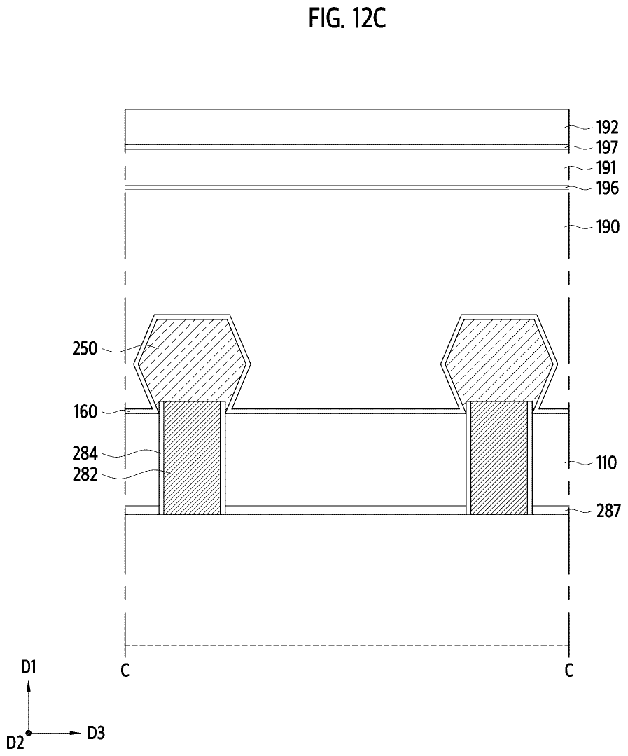

Referring to FIGS. 12A to 12C, following the process of being filled with the metal material described above, the CMP process may be performed. In FIGS. 12A to 12C, so that it may be easier to understand a planarized and removed portion compared to FIGS. 11A to 11C, a lower surface of the second deposition layer L2 illustrated in FIGS. 11A to 11C is marked with a dashed line.

The lower surface composing the semiconductor device 10 according to an embodiment may be polished mechanically and chemically and planarized through the CMP process. For example, by polishing mechanically and chemically up to a height at which the lower side surfaces of the first to third gate rear side structures 271, 272, and 273 described above are surrounded by the substrate 100, the second deposition layer L2 formed in FIGS. 11A to 11C may be removed. For example, in addition to the second deposition layer L2, at least a portion of the lower portions of the first to third gate rear side structures 271, 272, and 273 may also be removed together in this case. Here, mechanical and chemical polishing may indicate that a rotating polishing pad may be in continuous contact with the second deposition layer L2 and generate heat, and chemical slurry (for example, hydrogen peroxide) may be supplied in this process and oxidize the second deposition layer L2 to polish the second deposition layer L2 in a complementary manner. As at least a portion of the substrate (100 of FIGS. 11A to 11C) is removed, the rear side base pattern 101 may be formed. For example, as the lower surface composing the semiconductor device 10 is polished mechanically and chemically and planarized through the CMP process, a portion remaining after a portion of the substrate 100 is removed may be the rear side base pattern 101.

In addition, as a portion of the second deposition layer L2 is removed, the substrate 100 surrounding the first to third gate rear side structures 271, 272, and 273 may be exposed at the lower side surfaces thereof, and an upper surface of the substrate 100 may be oxidized by the mechanical and chemical polishing, and accordingly, the substrate 100 may include oxide. The substrate 100 including oxide formed between the first to third gate rear side structures 271, 272, and 273, the first rear side source/drain contact 281, and the second rear side source/drain contact 282 may function as the first blocking film 287 described above. Oxide may also be formed in a portion of the lower surfaces of the first to third gate rear side structures 271, 272, and 273 in the polishing process, which may be removed by subsequent intermediate stages in FIGS. 13A to 13C.

Referring to FIGS. 13A to 13C, in an embodiment, an insulating film may be formed by applying an insulating material to the entire area of the lower surface composing the semiconductor device 10. The insulating film formed in this case may be the first rear side interlayer insulating film 290 described above. When the first rear side interlayer insulating film 290 is formed below the first metal structure 270 and the second metal structure 280 and the upper surface thereof comes into contact with the lower surface of the first blocking film 287, additional photo process and etching process may be performed. According to an embodiment, through a subsequent etching process, a region overlapping the first rear side source/drain contact 281, the second rear side source/drain contact 282, and the second gate rear side structure 272 in the first direction D1 may be etched. The etched region may be a region where the first via connection part 265 and the second via connection part 266 described above are formed. Further, in the etching process, oxide formed in a portion of the lower surfaces of the second gate rear side structure 272, the first rear side source/drain contact 281, and/or the second rear side source/drain contact 282 described above may be removed.

As described above according to an embodiment, the first to third gate rear side structures 271, 272, and 273 may be formed in accurate positions at the side of the first rear side source/drain contact 281 and the second rear side source/drain contact 282.

The detailed description above has been provided by way of example for illustrative purposes. Furthermore, the above descriptions represent illustrative embodiments of the present disclosure, and the present disclosure may be used in various other combinations, changes, and environments. For example, the present disclosure may be changed or modified within the scope of the inventive concept disclosed in the specification, the equivalents to the written descriptions, and/or the technology or knowledge of those of ordinary skill in the pertinent art. The above disclosure describes illustrative embodiments by way of example for implementing the technical spirit of the present disclosure, and various changes may be made depending on the detailed application fields, design criteria and purposes based on the teachings of the present disclosure. Therefore, the detailed description as provided above is not intended to limit the present disclosure to the described embodiments, which were provided for description by way of example for efficient understanding without limitation thereto. In addition, the appended claims are to be construed as also including other embodiments.

What is claimed is:

1. A semiconductor device comprising:
a base pattern;
a first metal structure penetrating the base pattern in a first direction;
at least one gate structure including a gate electrode disposed on the first metal structure in the first direction;
a second metal structure penetrating the base pattern in the first direction and spaced adjacent to the first metal structure in a second direction intersecting the first direction; and
a source/drain structure including at least one of a source electrode or a drain electrode disposed on the second metal structure in the first direction,
wherein the first metal structure and the second metal structure are electrically separated from each other by a blocking film.

2. The semiconductor device of claim 1, wherein the blocking film includes:
a first blocking film formed at a lower portion in the first direction of the base pattern and configured to surround at least a portion of a side surface of the first metal structure; and
a second blocking film configured to surround at least a portion of a side surface of the second metal structure.

3. The semiconductor device of claim 2,
wherein the first blocking film is formed between the second blocking film and the first metal structure.

4. The semiconductor device of claim 1, wherein the first metal structure has a shape with an increasing width from an upper portion of the first metal structure toward a lower portion.

5. The semiconductor device of claim 2, wherein a lower surface of the first metal structure and a lower surface of the second metal structure are positioned at a substantially same level in the first direction.

6. The semiconductor device of claim 5, wherein the lower surface of the first metal structure is positioned at a substantially same level as a lower surface of the first blocking film and a lower surface of the second blocking film.

7. The semiconductor device of claim 2, wherein a distance in the first direction from a lower surface of the base pattern to an upper surface of the second metal structure is greater than a distance in the first direction from the lower surface of the base pattern to an upper surface of the first metal structure.

8. The semiconductor device of claim 7, wherein the upper surface of the second metal structure is positioned on a substantially same level as an upper surface of the second blocking film, and
wherein the upper surface of the second metal structure is in contact with a lower surface of the source/drain structure.

9. The semiconductor device of claim 2, wherein one portion of the second blocking film is in contact with the gate structure,
wherein another portion of the second blocking film is in contact with the base pattern, and
wherein yet another portion of the second blocking film is in contact with the first blocking film.

10. The semiconductor device of claim 2, wherein the first blocking film includes oxide and the second blocking film includes silicon nitride.

11. The semiconductor device of claim 10, wherein the first blocking film is formed in a polishing process of the first metal structure and the second metal structure.

12. The semiconductor device of claim 2, wherein the first metal structure is configured to penetrate a gate insulating film and in contact with a lower surface of the gate electrode.

13. The semiconductor device of claim 1, further comprising:
an active pattern surrounded by the gate structure on the base pattern,
wherein the source/drain structure is disposed to be connected to the active pattern in the second direction,
wherein the first metal structure is a rear side gate contact, and
wherein the second metal structure is a rear side source/drain contact.

14. The semiconductor device of claim 1, wherein the first metal structure is in contact with a first rear side via connected to a first wiring line disposed in the first direction, and
wherein the second metal structure is in contact with a second rear side via connected to a second wiring line disposed in the first direction.

15. A semiconductor device comprising:
a rear side base pattern;
an active pattern on the rear side base pattern;
a gate structure including a gate electrode configured to surround the active pattern disposed in a first direction;
a first source/drain structure and a second source/drain structure disposed on the rear side base pattern in the first direction, disposed to be connected to the active pattern in a second direction intersecting the first direction, and disposed to be spaced apart from each other with the gate structure in between in the second direction;
a rear side gate contact formed to penetrate the rear side base pattern in the first direction and connected to the gate structure;
a first rear side source/drain contact connected to the first source/drain structure; and
a second rear side source/drain contact connected to the second source/drain structure,
wherein the first rear side source/drain contact, the rear side gate contact, and the second rear side source/drain contact are disposed to be spaced apart sequentially in the second direction, and
wherein a blocking film is interposed between the rear side gate contact and the first rear side source/drain contact and between the rear side gate contact and the second rear side source/drain contact.

16. The semiconductor device of claim 15, wherein the blocking film includes:
an oxide film formed at a lower portion of the rear side base pattern configured to surround a side surface of the rear side gate contact; and
a liner configured to surround each of a side surface of the first rear side source/drain contact and a side surface of the second rear side source/drain contact.

17. The semiconductor device of claim 16, wherein the rear side gate contact decreases in width from an upper portion toward a lower portion, and
wherein the oxide film is interposed between the lower portion of the rear side gate contact and the liner.

18. The semiconductor device of claim 17, wherein at least a portion of a lower surface of the first source/drain structure and at least a portion of a lower surface of the second source/drain structure are recessed,
wherein, based on the first direction, a lower surface of the rear side base pattern, a lower surface of the first rear side source/drain contact, a lower surface of the second rear side source/drain contact, and a lower surface of the rear side gate contact are all on a substantially same level, and
wherein, based on the first direction, each vertical level from the lower surface of the rear side base pattern to an upper surface of the first rear side source/drain contact and an upper surface of the second rear side source/drain contact is greater than a vertical level to an upper surface of the rear side gate contact.

19. The semiconductor device of claim 18, wherein a lower surface of the oxide film and a lower surface of the liner are on a substantially same level as the lower surface of the rear side base pattern, and
wherein a vertical level from the lower surface of the rear side base pattern to an upper surface of the liner based on the first direction is greater than a vertical level from the lower surface of the rear side base pattern to the upper surface of the rear side gate contact based on the first direction.

20. A semiconductor device comprising:
a rear side base pattern;
an active pattern on the rear side base pattern;
a gate structure including a gate electrode configured to surround the active pattern disposed in a first direction;
a first source/drain structure and a second source/drain structure disposed on the rear side base pattern in the first direction, connected to each other through the active pattern, and disposed to be spaced apart from each other with the gate structure in between in a second direction intersecting the first direction;
a first gate rear side structure, a second gate rear side structure, and a third gate rear side structure configured to penetrate the rear side base pattern in the first direction, formed to decrease in width from upper portions toward lower portions, and connected to the gate structure;
a first rear side source/drain contact connected to the first source/drain structure;
a second rear side source/drain contact connected to the second source/drain structure;
a first blocking film formed at a lower portion of the rear side base pattern configured to surround side surfaces of the first gate rear side structure, the second gate rear side structure, and the third gate rear side structure; and
a second blocking film configured to surround each of a side surface of the first rear side source/drain contact and a side surface of the second rear side source/drain contact,
wherein the first blocking film is in contact with at least a portion of each of the side surfaces of the first gate rear side structure, the second gate rear side structure, and the third gate rear side structure and at least a portion of a side surface of the second blocking film, and
wherein some of the first gate rear side structure, the second gate rear side structure, and the third gate rear side structure are in contact with an interlayer insulating film in the first direction and others are in contact with a rear side via connected to a wiring line.
